(19) United States
(12) Patent Application Publication
(10) Pub. No.: US 2010/0230789 A1
(43) Pub. Date: Sep. 16, 2010

(54) SEMICONDUCTOR DEVICE AND MANUFACTURING METHOD THEREOF

(75) Inventors: Chiko Yorita, Fujisawa (JP); Yuji Shirai, Tokyo (JP); Hirokazu Nakajima, Tokyo (JP); Hiroshi Ozaku, Tokyo (JP); Tomonori Tanoue, Tokyo (JP); Hiroshi Okabe, Tokyo (JP); Tsutomu Hara, Yokohama (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/724,268

(22) Filed: Mar. 15, 2010

(30) Foreign Application Priority Data
Mar. 16, 2009 (JP) 2009-062851

(51) Int. Cl. H01L 23/552; H01L 21/78; H01L 21/56

(52) U.S. Cl. 257/659; 438/113; 257/690; 257/723; 438/124; 257/E21.599; 257/E21.502; 257/E23.114; 257/E23.141

(57) ABSTRACT

A technology is provided which allows a reduction in the size of a semiconductor device without degrading an electromagnetic shielding effect and reliability against reflow heating. After a plurality of components are mounted over a component mounting surface of a module substrate, a resin is formed so as to cover the mounted components. Further, over surfaces (upper and side surfaces) of the resin, a shield layer including a laminated film of a Cu plating film and an Ni plating film is formed. In the shield layer, a plurality of microchannel cracks are formed randomly along grain boundaries and in a net-like configuration without being coupled to each other in a straight line, and form a plurality of paths extending from the resin to a surface of the shield layer by the microchannel cracks.

### CROSS-REFERENCE TO RELATED APPLICATIONS

The disclosure of Japanese Patent Application No. 2009-62851 filed on Mar. 16, 2009 including the specification, drawings and abstract is incorporated herein by reference in its entirety.

### BACKGROUND OF THE INVENTION

The present invention relates to a semiconductor device and a manufacturing technology therefore and, particularly to a technology which is effective when applied to an RF power amplifier module and to a product in which the RF power amplifier module is mounted over a mounting substrate (mother board) such as, e.g., mobile communication equipment.

For example, in International Publication Pamphlet WO 02/63688 (Patent Document 1), an RF power amplifier device having a flat and elongated hexahedral structure is disclosed in which a package includes a module substrate comprised of, e.g., a ceramic wiring board, and a cap which is a metal molded product having an electromagnetic shielding effect.

Also, in Japanese Unexamined Patent Publication No. 2004-297054 (Patent Document 2), a semiconductor device is disclosed which includes wiring buried in an insulating layer, circuit elements mounted over the insulating film, a molding layer formed so as to cover the circuit elements, and a conductive shielding film formed so as to cover the molding layer, wherein the wiring and the shielding film are electrically coupled to each other, and the shielding film functions as a shield from an electromagnetic wave.

Also, in Japanese Unexamined Patent Publication No. 2004-172176 (Patent Document 3), a circuit module is disclosed which includes an insulating layer covering a plurality of components disposed over a substrate, a grounding electrode provided in a state exposed from the insulating layer over the substrate, and a shield layer formed outside the insulating layer, and coupled to the grounding electrode, wherein the respective end surfaces of the substrate and the shield layer are positioned in the same plane.

Also, in Japanese Unexamined Patent Publication No. 2006-286915 (Patent Document 4), a circuit module is disclosed which includes a circuit substrate including a wiring pattern and a ground layer, a set of electronic components mounted over the mounting surface of the circuit substrate, an insulating resin layer molding therein the set of electronic components, and a conductive resin layer formed over the surface of the insulating resin layer, and including flake-like metal.

Also, in Japanese Unexamined Patent Publication No. 2005-109306 (Patent Document 5), an electronic component package is disclosed which includes a circuit substrate having a ground pattern, mounted components comprised of electronic components mounted over the upper surface of a circuit substrate, a molding structure comprised of an epoxy resin containing an inorganic filler, and molding therein the mounted components, and electromagnetic shield layers (an electroless copper plating layer, an electrolytic copper plating layer, and a coating layer) formed over the surface of the molding structure, and grounded to the ground pattern.

Also, in Japanese Unexamined Patent Publication No. 2005-333047 (Patent Document 6), a manufacturing method of a module with embedded circuit components is disclosed in which a plurality of units having mounted components and formed over a substrate are molded with an insulating resin, the insulating resin is cured, the substrate is processed to be formed with trenches in a grid-like configuration each having a depth of about half the depth of the substrate, a plating surface layer is formed, and then the remaining portion of the substrate corresponding to about half the original thickness thereof is removed so that a discrete module is provided.

### [Prior Art Documents]

### [Patent Documents]

### [Patent Document 1]

### International Publication Pamphlet WO 02/63688

### [Patent Document 2]

### Japanese Unexamined Patent Publication No. 2004-297054

### [Patent Document 3]

### Japanese Unexamined Patent Publication No. 2004-172176

### [Patent Document 4]

### Japanese Unexamined Patent Publication No. 2006-286915

### [Patent Document 5]

### Japanese Unexamined Patent Publication No. 2005-109306

### [Patent Document 6]

### Japanese Unexamined Patent Publication No. 2005-333047

### SUMMARY OF THE INVENTION

Currently, as a shield of an RF module mounted over a mounting substrate such as a mobile phone, a metal cap formed by molding a material containing stainless steel as a main component in a die is used. The metal cap has an advantage of a high electromagnetic shielding effect. However, as the height of the RF module using the metal cap, the respective heights of the individual components provided in the RF module and a given clearance (gap or allowance) in accordance with a purpose are needed so that the height of the RF module including the thickness of the metal cap used therein is as high as, e.g., about 1.8 mm. Since the entire RF module is surrounded by the meal cap, a margin region for mounting the metal cap is needed around a mounting substrate over which the RF module is mounted. This undesirably increases the size of a product in which the RF module is mounted over the mounting substrate. Accordingly, for the RF module desired to be smaller in size, lower in cost and higher in functionality, a shielding method as a substitute for the metal cap is examined.

As the shielding method as a substitute for the metal cap, the present inventors have examined a metallic film (hereinafter referred to as a shield layer) comprised of, e.g., a plating film or a conductive paste film. For example, the shield layer can be formed as follows. First, a plurality of components are mounted over the component mounting surface of a module substrate, and then the components are covered with a mold resin. Subsequently, from the upper surface of the mold resin, incisions reaching the side surfaces of an electrode coupled to ground wiring of the module substrate are made. Thereafter, a shield layer is formed over the surfaces (the upper surface of the mold resin and the side surfaces of the incision portions) of the mold resin including the inner walls of the incision portions. The plating film is formed by an electrolytic plating method or an electroless plating method. The conductive paste film is formed by a printing method or by a spray coating method based on spraying. The thickness of the shield layer having an electromagnetic shielding effect is determined by the frequency of a product in which the RF module is used, the conductivity of the shield layer, and the like.

However, the shield layer including the plating film has various technical problems described hereinbelow.

The present inventors performed a thermal shock test at −55 to 125° C. on a package in which the plating film was formed over the surface of the mold resin. As a result, in the test, data showing sufficient reliability against a thermal shock was obtained. However, as a result of performing a JEDEC LEVEL 2 moisture absorption test (the package was allowed to stand at a temperature of 85° C. and a relative humidity of 60% for 168 hours, and then heated to 260° C. by four ref lows), swelling occurred between the plating film and the mold resin to cause such problems as the degradation of the electrical characteristics of the RF module and a reduction in electromagnetic shielding effect. It is considered that the above-mentioned swelling resulted from the fact that moisture contained in the module substrate, moisture contained in the mold resin, or moisture that had entered into the interface between the module substrate and the module resin was evaporated by reflow heating at 260° C. performed with respect to the package, and momentary volume expansion upon the evaporation raised the plating film, and caused the peeling thereof.

As for the shield layer including the conductive paste film, it also has various technical problems described hereinbelow.

The conductive paste film can be formed by a printing method or a spray coating method. As solutions to problems presented by a conductive paste film formed by a printing method, there can be listed ensuring post-printing flatness, and filling of the incision portions with a paste without the formation of a void. Further, when the filled incision portions are to be cut, it is necessary to leave the conductive paste film having a given thickness over each of the side surfaces of the package. To that end, it is required to consider an amount of warping of a module substrate, the tolerance of a cutting width, an amount of distortion of a cutting blade, and the like.

In a conductive paste film formed by a spray coating method, the thickness of the conductive paste film over the upper surface of a package is inevitably large as a result of spray coating a paste, while the thickness of the conductive paste film over each of the side surfaces of the package is inevitably small and non-uniform. Accordingly, it is required to coat a conductive paste film having a thickness which is the sum of a thickness needed to ensure the electromagnetic shielding effect and a thickness calculated in consideration of coating variations, which undesirably increases material cost.

The present inventors also performed a thermal shock test at −55 to 125° C. on a package in which a conductive paste film was formed over the surface of a mold resin. However, in about 100 cycles, a crack having a depth of several micrometers and a length in excess of 100 μm was formed in the conductive paste film, and the electromagnetic shielding effect was not obtained.

Within the module substrate, a ground electrode (ground potential electrode, ground layer, or ground wiring) having a planar structure parallel with the top surface or back surface of the module substrate is provided. In the case of a conventional module substrate not provided with a shield layer, a region where the ground electrode is formed is substantially limited to a via region for heat dissipation immediately under a transistor formed over the component mounting surface of the module substrate. When a shield layer is formed in such a module substrate in which a ground electrode is provided only in a via region for heat dissipation, it is necessary to provide a large number of vias for ground electrode even in the outer peripheral portion of the module substrate to prevent performance degradation due to an increase in the loss of a matching circuit. However, when the vias for ground electrode are disposed in the outer peripheral portion of the module substrate, a problem occurs that the layout of the individual electrodes within the module substrate is significantly limited with regard to the design of signal lines and a ground line.

In the case where a large number of vias for ground electrode cannot be provided in the outer peripheral portion of the module substrate, it follows that the potential of the via region for heat dissipation is used as a ground potential. However, when a pattern needed for the coupling thereof is elongated, a problem occurs that, due to the inductance component of the pattern, the electromagnetic shielding effect cannot be sufficiently obtained.

In the case of coupling the shield layer to the ground electrode with wiring patterns provided over the back surface of the module substrate, in order to increase the number of coupling portions by reducing the spacing between the coupling portions, it is required to set the plurality of wiring patterns provided over the back surface of the module substrate at the ground potential, which causes a problem that assignment of signals to the wiring patterns is significantly restricted.

It is therefore an object of the present invention to provide a technology which allows a reduction in the size of a semiconductor device without degrading an electromagnetic shielding effect and reliability against reflow heating.

The above and other objects and novel features of the present invention will become apparent from the description of the present specification and the accompanying drawings.

The following is a brief description of an embodiment of a representative aspect of the invention disclosed in the present application.

The embodiment is a semiconductor device having an RF module, which includes a module substrate using a wiring layer of a part of inner-layer wiring as ground wiring, a plurality of components mounted over a component mounting surface of the module substrate, a resin formed so as to cover the mounted components, and a shield layer including a laminated film of a Cu plating film and an Ni plating formed over a surface of the resin. In the shield layer, a plurality of microchannel cracks are formed randomly along a grain boundary and in a net-like configuration without being coupled to each other in a straight line, and form a plurality of paths extending from the resin to a surface of the shield layer.

The embodiment is a manufacturing method of a semiconductor device including an RF module, which includes the steps of preparing a sheet-like first wiring substrate in which a plurality of module regions are arranged in a first direction and in a second direction orthogonal to the first direction, mounting a plurality of components over a component mounting surface of the first wiring substrate, molding the mounted components with a resin, cutting, from above the resin, the resin and a part of the first wiring substrate in the first direction and in the second direction to make an incision around each of the module regions, forming a shield layer including a laminated film of a first film having an electromagnetic shielding function and a second film having an anticorrosive function over a surface of the resin and in the incision portion of the first wiring substrate by an electroless plating method, cutting the first wiring substrate located below the incision portion of the first wiring substrate into the individual RF modules, and disposing the RF modules over a main surface of a mother board via a solder, and then performing reflow heating.

The following is a brief description of an effect obtained by the embodiment of the representative aspect of the invention disclosed in the present application.

It is possible to provide a technology which allows improvements in the characteristics of a semiconductor device, especially a reduction in the size of the semiconductor device without degrading an electromagnetic shielding effect and reliability against reflow heating.

### BRIEF DESCRIPTION OF THE DRAWINGS

FIG. 1 shows an example of a system of a digital mobile phone set according to an embodiment of the present invention;

FIG. 2 shows an example of a circuit of a power amplifier used in the digital mobile phone set according to the embodiment of the present invention;

FIG. 3 shows an example of a principal-portion cross-sectional view illustrating an internal structure of a semiconductor chip in which amplification stages of a power amplifier according to the embodiment of the present invention are formed of n-channel LDMOSFETs;

FIG. 4 shows an example of primary mounting of an RF module in the digital mobile phone set according to the embodiment of the present invention;

FIGS. 5(a) to 5(d) are principal-portion plan views of each of a plurality of insulator plates for illustrating a module substrate having a multilayer wiring structure, and formed integrally by laminating the insulator plates according to the embodiment of the present invention, in which FIG. 5(a) shows first-layer wiring, FIG. 5(b) shows second-layer wiring, FIG. (c) shows third-layer wiring, and FIG. 5(d) shows fourth-layer wiring;

FIG. 6 is a surface diagram of a shield layer according to the embodiment of the present invention;

FIG. 7 is a cross-sectional photograph of the shield layer according to the embodiment of the present invention;

FIG. 8 is an illustrative view of a sample for which the water vapor permeability of the shield layer according to the embodiment of the present invention is measured;

FIG. 9 is graph showing the result of measuring the water vapor permeability of the shield layer according to the embodiment of the present invention;

FIG. 10 is graph showing the relationship between the water vapor permeability of the shield layer and the thickness of the shield layer according to the embodiment of the present invention;

FIG. 11 is a schematic view of a simulation model used in verifying an electromagnetic shielding effect according to the embodiment of the present invention;

FIG. 12 is a graph showing the relationship between the electromagnetic shielding effect and a conductivity obtained by the simulation according to the embodiment of the present invention;

FIG. 13 is a graph showing the relationship between the electromagnetic shielding effect and the thickness of the shield layer obtained by the simulation according to the embodiment of the present invention;

FIGS. 14(a) and 14(b) are graphs respectively showing the relationship between an amount of noise generated in an RF module in which a shield layer is not formed over the surface of a resin and a frequency and the relationship between an amount of noise generated in an RF module in which a shield layer is formed over the surface of a resin and a frequency;

FIG. 15 is a graph illustrating the relationship between a noise level and the number of coupling portions (number of coupling points) between ground wiring of the module substrate and the shield layer;

FIG. 16 is a principal-portion schematic view showing an example of a semiconductor device in which the RF module according to the embodiment of the present invention is secondary mounted;

FIG. 17 is a principal-portion schematic view showing an example of a semiconductor device in which a conventional RF module using a metal cap is secondary mounted;

FIG. 18 is a principal-portion schematic view showing another example of the semiconductor device in which the conventional RF module using the metal cap is secondary mounted;

FIG. 19 is a principal-portion schematic view showing still another example of the semiconductor device in which the conventional RF module using the metal cap is secondary mounted;

FIG. 20 is a process step view illustrating the procedure of assembly of the RF module according to the embodiment of the present invention;

FIG. 21 is a principal-portion cross-sectional view of the semiconductor device illustrating a manufacturing method thereof according to the embodiment of the present invention;

FIG. 22 is a principal-portion cross-sectional view of the semiconductor device illustrating the manufacturing method thereof, which is subsequent to FIG. 21;

FIG. 23 is a principal-portion cross-sectional view of the semiconductor device illustrating the manufacturing method thereof, which is subsequent to FIG. 22;

FIG. 24 is a principal-portion cross-sectional view of the semiconductor device illustrating the manufacturing method thereof, which is subsequent to FIG. 23;

FIG. 25 is a principal-portion cross-sectional view of the semiconductor device illustrating the manufacturing method thereof, which is subsequent to FIG. 24;

FIGS. 26(a) and 26(b) are a principal-portion plan view and a principal-portion cross-sectional view of the semiconductor device each illustrating the manufacturing method thereof, which are subsequent to FIG. 24;

FIG. 27 is a principal-portion cross-sectional view of the semiconductor device illustrating the manufacturing method thereof, which is subsequent to FIGS. 25 and 26; and

FIG. 28 is a principal-portion cross-sectional view of the semiconductor device illustrating the manufacturing method thereof, which is subsequent to FIG. 27.

### DESCRIPTION OF THE PREFERRED EMBODIMENTS

In the following embodiment, if necessary for the sake of convenience, the following embodiment will be described by dividing it into a plurality of sections or embodiments. However, they are by no means irrelevant to each other unless shown particularly explicitly, and are mutually related to each other such that one of the sections or embodiments is a variation or a detailed or complementary description of some or all of the others.

When the number and the like (including the number, numerical value, amount, and range thereof) of elements are referred to in the following embodiment, they are not limited to specific numbers unless shown particularly explicitly or unless they are obviously limited to specific numbers in principle. The number and the like of the elements may be not less than or not more than specific numbers. It will be easily appreciated that, in the following embodiment, the components thereof (including also elements, steps, and the like) are not necessarily indispensable unless shown particularly explicitly or unless the components are considered to be obviously indispensable in principle. Likewise, if the shapes, positional relationship, and the like of the components and the like are referred to in the following embodiment, the shapes and the like are assumed to include those substantially proximate or similar thereto unless shown particularly explicitly or unless obviously they are not in principle. The same holds true with regard to the foregoing numerical value and range.

In the drawings used in the following embodiment, even a plan view may be hatched for clarity of illustration. Also, in the following embodiment, a metal insulator semiconductor field effect transistor (MISFET) which is a representative of a field effect transistor may be abbreviated as MIS. In the following embodiment, when a wafer is mentioned, it primarily indicates a silicon (Si) single-crystal wafer, but is not limited thereto. It is assumed that a wafer also indicates a silicon-on-insulator (SOI) wafer, an insulating film substrate for forming thereover an integrated circuit, or the like. It is also assumed that the shape of a wafer is not limited to a circular shape or a nearly circular shape, but also includes a square shape, a rectangular shape, and the like.

Hereinbelow, the embodiment of the present invention will be described in detail with reference to the drawings. Throughout the drawings for illustrating the following embodiment of the present invention, members having the same functions will be provided with the same reference numerals, and a repeated description thereof is omitted

Before the embodiment of the present invention is described in detail, the meanings of terms in the following embodiment will be described as follows.

Global system for mobile communication (GSM) indicates one of wireless communication methods used in a digital mobile phone or the standard thereof. In the GSM, there are three frequency bands of electric waves used therein. A 900 MHz band is referred to as GSM 900 or merely GSM. A 1800 MHz band is referred to as GSM 1800, DCS (abbreviation of Digital Cellular System) 1800, or PCN (abbreviation of Personal Communication Network). A 1900 MHz band is referred to as GSM 1900, DCS 1900, or PCS (abbreviation of Personal Communication Services). Note that GSM 1900 is mainly used in North America. In North America, besides GSM 1900, GSM 850 of a 850 MHz band may also be used. A gaussian filtered minimum shift keying (GMSK) modulation method is a method used in the communication of a sound/voice signal, which shifts the phase of a carrier wave in accordance with transmission data. An enhanced data GSM environment (EDGE) modulation method is a method used in data communication, and obtained by further adding an amplitude shift to the phase shift of the GMSK modulation.

In the following embodiment, among a plurality of surface mounted components mounted over one module substrate, a chip in which one or a plurality of active elements are formed over one chip substrate is called a semiconductor chip, and a chip in which a passive element such as, e.g., a capacitor, an inductor, a resistor, or the like is formed over one chip substrate is called a chip component. Further, a chip in which one passive element is formed over one chip substrate is called a single-element chip component, and a chip in which a plurality of passive elements are formed over one chip substrate is called an integrated chip component. In the case where it is necessary to distinguish the both types of chips from each other, they are mentioned as the integrated chip component and the single-element chip component.

“Microchannel cracks” used in the following embodiment are clearances present along grain boundaries in a shield layer, which have widths of not more than 200 nm, and reach a resin serving as an underlying layer.

In the present embodiment, a description will be given of the case where the present invention is applied to a digital mobile phone (mobile communication equipment) which transmits information using a network according to, e.g., the GSM method.

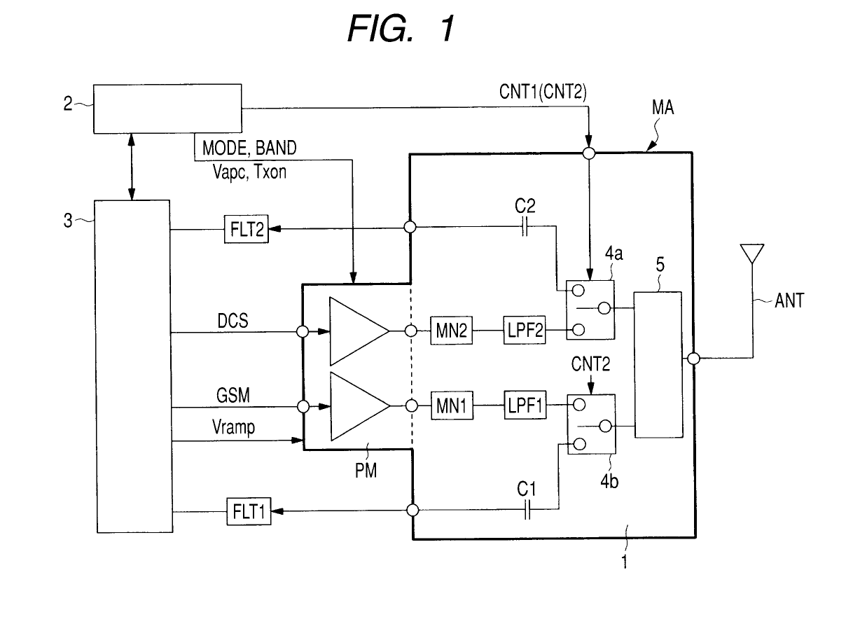

FIG. 1 shows an example of a system of a digital mobile phone according to the present embodiment. In the drawing, PM denotes a power amplifier, ANT denotes an antenna for the transmission/reception of a signal electric wave, 1 denotes a front end device, 2 denotes a baseband circuit which converts a sound/voice signal to a baseband signal, converts a reception signal to a sound/voice signal, and generates a modulation-method switch signal and a band switch signal, 3 denotes a modulation/demodulation circuit which down-converts and demodulates the reception signal, generates a baseband signal, and modulates a transmission signal, and FLT1 and FLT2 denote filters for removing noise and an interference wave from the reception signal. The filter FLT1 is for GSM, and the filter FLT2 is for DCS.

The front end device 1 has impedance matching circuits MN1 and MN2, lowpass filters LPF1 and LPF2, switch circuits 4a and 4b, capacitors C1 and C2, and a demultiplexer 5. The impedance matching circuits MN1 and MN2 are circuits coupled to the transmission output terminal of the power amplifier PM to perform impedance matching. The lowpass filters LPF1 and LPF2 are circuits which attenuate harmonics. The switch circuits 4a and 4b are circuits for transmission/reception switching. The capacitors C1 and C2 are elements which cut dc components from the reception signal. The demultiplexer 5 is a circuit which demultiplexes a GSM 900 signal and a DCS 1800 signal. In the digital mobile phone as the present embodiment, the power amplifier PM and the front end device 1 have been assembled into one module MA.

Switch signals CNT1 and CNT2 of the switch circuits 4a and 4b are supplied from the foregoing baseband circuit 2. The baseband circuit 2 includes a plurality of semiconductor integrated circuits such as a digital signal processor (DSP), a microprocessor, and a semiconductor memory.

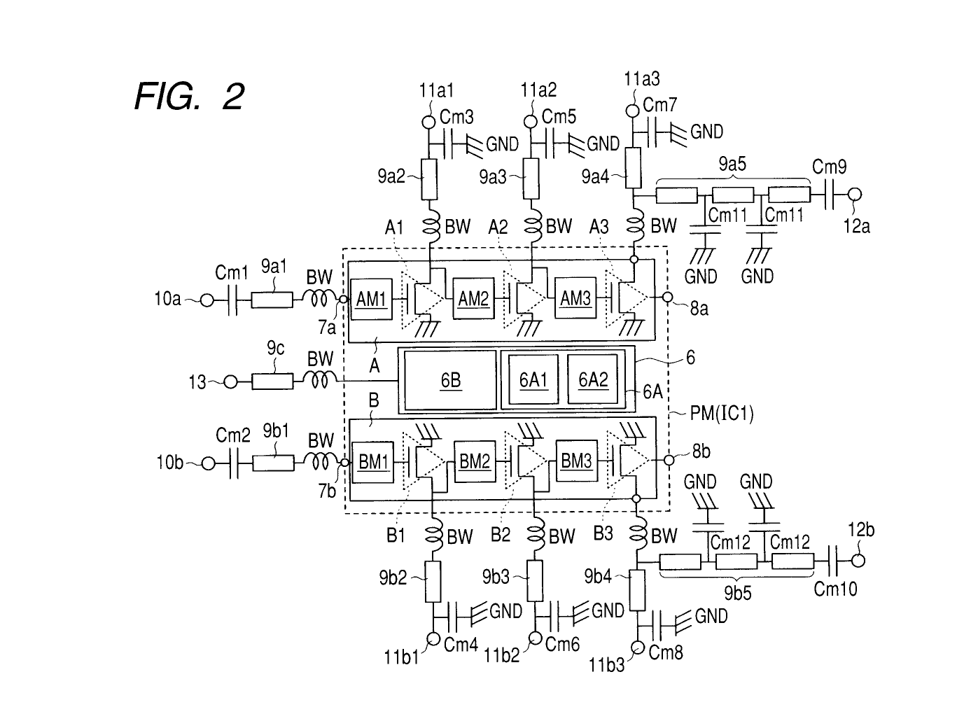

FIG. 2 shows an example of a circuit of the power amplifier PM.

The power amplifier PM can use two frequency bands which are, e.g., GSM 900 and DCS 1800 (in a dual-band system), and allows the use of two communication methods which are the GMSK modulation method and the EDGE modulation method in the respective frequency bands.

The power amplifier PM has a power amplification circuit A for GSM 900, a power amplification circuit B for DCS 1800, and a peripheral circuit 6 which performs the control, correction, and the like of amplifying operations by the power amplification circuits A and B. The power amplification circuits A and B have respective three amplification stages A1 to A3 and B1 to B3, and respective three matching circuits AM1 to AM3 and BM1 to BM3. That is, input terminals 7a and 7b of the power amplifier PM are electrically coupled to the inputs of the first amplification stages A1 and B1 via the matching circuits AM1 and BM1 for signal input. The outputs of the first amplification stages A1 and B1 are electrically coupled to the inputs of the second amplification stages A2 and B2 via the inter-stage matching circuits AM2 and BM2. The outputs of the second amplification stages A2 and B2 are electrically coupled to the inputs of the final amplification stages A3 and B3 via the inter-stage matching circuits AM3 and BM3. The outputs of the final amplification stages A3 and B3 are electrically coupled to output terminals 8a and 8b. In the present embodiment, such elements forming the power amplification circuits A and B are provided in one semiconductor chip Id1.

The peripheral circuit 6 has a control circuit 6A, a bias circuit 6B which applies a vias voltage to each of the amplification stages A1 to A3 and B1 to B3, and the like. The control circuit 6A generates desired voltages applied to the power amplification circuits A and B, and has a power source control circuit 6A1 and a bias voltage generation circuit 6A2. The power source control circuit 6A1 generates a first power source voltage to be applied to each of the respective outputs of the amplification stages A1 to A3 and B1 to B3. The bias voltage generation circuit 6A2 generates a first control voltage for controlling the bias circuit 6B.

In the present embodiment, when the power source control circuit 6A1 generates the first power source voltage based on an output level specifying signal supplied from the baseband circuit 2 outside the power amplifier PM, the bias voltage generation circuit 6A2 generates the first control voltage based on the first power source voltage generated in the power source control circuit 6A1. The baseband circuit 2 generates the output level specifying signal. The output level specifying signal specifies the output level of each of the power amplification circuits A and B, and is generated based on the distance between the mobile phone and a base station, i.e., on the output level in accordance with the intensity of an electric wave. In the present embodiment, such elements forming the peripheral circuit 6 are also provided in one semiconductor chip IC1.

External terminals (pad electrodes) formed over a main surface (surface formed with the circuit elements) of the semiconductor chip IC1 forming the power amplifier PM and substrate-side terminals formed over the component mounting surface of a module substrate mounting thereover the semiconductor chip IC1 are coupled to each other via bonding members (e.g., bonding wires BW), and the respective inputs/outputs of the individual amplification stages are electrically coupled to the transmission lines 9a1 to 9a5, 9b1 to 9b5, and 9c of the component mounting surface of the module substrate through the bonding members.

The transmission lines 9a1 and 9b1 coupled to the respective inputs of the first amplification stages A1 and B1 via the bonding wires BW are electrically coupled to respective input terminals 10a and 10b via respective capacitors Cm1 and Cm2. The transmission lines 9a2 and 9b2 electrically coupled to the respective outputs of the first amplification stages A1 and B1 via the bonding wires BW are electrically coupled to respective higher-potential power source terminals 11a1 and 11b1, and electrically coupled to a ground potential GND via respective capacitors Cm3 and Cm4 disposed respectively adjacent to the power source terminals 11a1 and 11b1. The transmission lines 9a3 and 9b3 electrically coupled to the respective outputs of the second amplification stages A2 and B2 via the bonding wires BW are electrically coupled to respective higher-potential power source terminals 11a2 and 11b2, and electrically coupled to the ground potential GND via respective capacitors Cm5 and Cm6 disposed respectively adjacent to the power source terminals 11a2 and 11b2. The transmission lines 9a4 and 9b4 electrically coupled to the respective outputs of the final amplification stages A3 and B3 via the bonding wires BW are electrically coupled to respective higher-potential power source terminals 11a3 and 11b3, and electrically coupled to the ground potential GND via respective capacitors Cm7 and Cm8 disposed respectively adjacent to the power source terminals 11a3 and 11b3. Further, the transmission lines 9a5 and 9b5 electrically coupled to the respective outputs of the final amplification stages A3 and B3 via the bonding wires BW are electrically coupled to output terminals 12a and 12b via respective capacitors Cm9 and Cm10, and electrically coupled to the ground potential GND via respective capacitors Cm11 and Cm12 which are disposed at midpoints in the respective lines. The transmission line 9c electrically coupled to the external terminal for controlling the peripheral circuit 6 via the bonding wire BW is electrically coupled to a control terminal 13. Each of the bonding wires BW has the function of an inductor. Each of the transmission lines 9a1 to 9a5 and 9b1 to 9b5 has the function of an inductor for impedance matching. Each of the capacitors Cm1 to Cm12 has the function of a capacitor for impedance matching, and formed of the chip components.

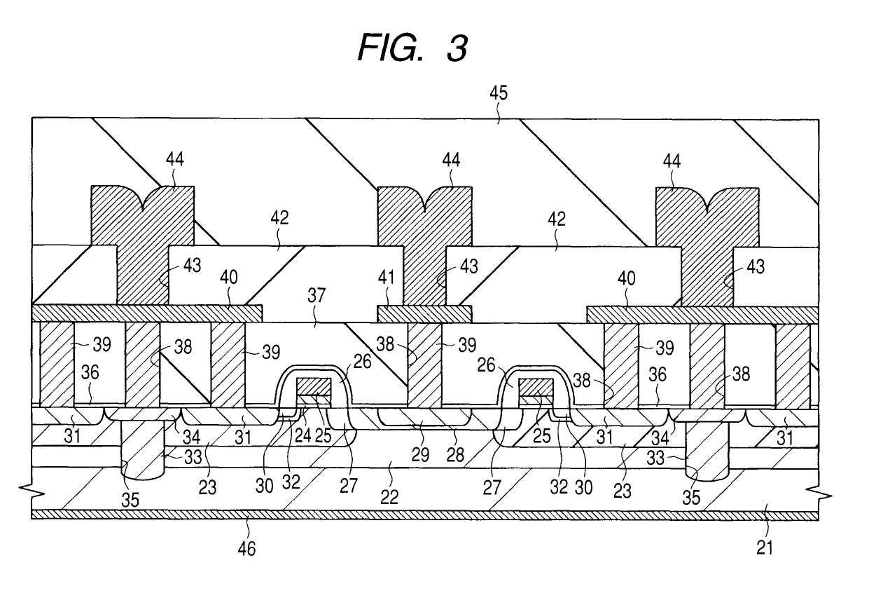

Next, a description will be given of a structure of a typical one of the various elements forming the power amplifier PM. Here, an example of an internal structure of the power amplifier PM in which the amplification stages A1 to A3 and B1 to B3 are formed of n-channel laterally diffused metal oxide semiconductor field effect transistors (LDMOSFETs) will be described using a principal-portion cross-sectional view shown in FIG. 3. The power amplifier PM is formed in one semiconductor chip IC1. In the present embodiment, the amplification stages are formed of the LDMOSFETs, but they are not limited thereto. For example, it is also possible to form the amplification stages of heterojunction bipolar transistors (HBTs).

A substrate 21 having the power amplifier PM formed therein is a low-resistance substrate comprised of, e.g., p⁺-type single-crystal silicon, and having a resistivity in a range of, e.g., about 1 to 10 mO-cm. Over the substrate 21, there is formed an epitaxial layer 22 comprised of, e.g., p⁻-type single-crystal silicon. The epitaxial layer 22 has a resistivity in a range of, e.g., about 20 mO-cm, which is higher than the resistivity of the above-mentioned substrate 21. Over the main surface of the epitaxial layer 22, there are formed the LDMOSFETs for the amplification stages A1 to A3 and B1 to B3, inductors for the matching circuits AM1 to AM3 and BM1 to BM3, capacitors having high quality-factor (high Q) values, and the transmission lines. The LDMOSFETs shown herein are unit MISFETs. Actually, a plurality of the unit MISFETs are coupled in parallel to form one amplification stage.

In parts of the main surface of an epitaxial layer 22, p-type wells 23 are formed. Each of the p-type wells 23 has the function of a punch-through stopper which inhibits the extension of a depletion layer from the drain of the corresponding LDMOSFET to the source thereof.

In the surface of each of the p-type wells 23, a gate insulating film 24 comprised of silicon dioxide is formed by, e.g., a thermal oxidation method or the like. Over the gate insulating film 24, a gate electrode 25 of the LDMOSFET is formed. The gate electrode 25 includes a laminated conductor film of, e.g., an n-type polysilicon film and a tungsten silicide (WSi₂) film formed thereover. The p-type well 23 under the gate insulating film 24 serves as a region where the channel of the LDMOSFET is to be formed. Over the side walls of the gate electrodes 25, sidewalls 26 comprised of silicon dioxide are formed.

In regions spaced apart from each other with the channel formation region of the epitaxial layer 22 interposed therebetween, the source and drain of the LDMOSFET are formed. The drain includes an n⁻-type offset drain region 27, an n-type offset drain region 28 formed in contact with the n⁻-type offset drain region 27 to be spaced apart from the channel formation region, and an n⁺-type drain region 29 formed in contact with the n-type offset drain region 28 to be further spaced apart from the channel formation region. Among the n⁻-type offset drain region 27, the n-type offset drain region 28, and the n⁺-type drain region 29, the n⁻-type offset drain region 27 closest to the gate electrode 25 has a lowest impurity concentration, and the n⁺-type drain region 29 most distant from the gate electrode 25 has a highest impurity concentration. As will be described later, the n⁻-type offset drain region 27 is formed by self alignment with respect to the gate electrode 25, and the n-type offset drain region 28 is formed by self alignment with respect to the sidewalls 26 over the side walls of the gate electrode 25.

Thus, a characteristic feature of the LDMOSFET shown in the present embodiment is that the offset drain region interposed between the gate electrode 25 and the n⁺-type drain region 29 is provided with a double offset structure, and the impurity concentration of the n⁻-type offset drain region 27 closest to the gate electrode 25 is adjusted to be relatively low, while the impurity concentration of the n-type offset drain region 28 spaced apart from the gate electrode 25 is adjusted to be relatively high.

The structure allows the depletion layer to expand between the gate electrode 25 and the drain and, consequently, a feedback capacitance formed between the gate electrode 25 and the n⁻-type offset drain region 27 adjacent thereto is reduced. In addition, since the impurity concentration of the n-type offset drain region 28 is high, an ON-resistance is also reduced. Since the n-type offset drain region 28 is formed at a position spaced apart from the gate electrode 25, it exerts slight influence on the feedback capacitance. That is, the LDMOSFET of the present embodiment can reduce each of the ON-resistance and the feedback capacitance which have had the trade-off relationship therebetween in a conventional LDMOSFET. Therefore, it is possible to improve the power added efficiency of the amplification circuit.

Meanwhile, the source of the LDMOSFET includes an n⁻-type source region 30 in contact with the channel formation region, and an n⁺-type source region 31 formed in contact with the n⁻-type source region 30 to be spaced apart from the channel formation region 30. The n⁻-type source region 30 in contact with the channel formation region is formed to be lower in impurity concentration, and shallower than the n⁺-type source region 31 spaced apart from the channel formation region. Under the n⁻-type source region 30, there is formed a p-type halo region 32 for inhibiting the diffusion of an impurity from the source to the channel formation region, and further inhibiting a short-channel effect. As will be described later, the n⁻-type source region 30 is formed by self alignment with respect to the gate electrode 25, and the n⁺-type source region 31 is formed by self alignment with respect to the sidewalls 26 over the side walls of the gate electrode 25.

In the end portion (end portion opposite to that in contact with the n⁻-type source region 30) of the n⁺-type source region 31, there is formed a p-type punch-through layer 33 in contact with the n⁺-type source region 31. In the vicinity of the surface of the p-type punch-through layer 33, there is formed a p⁺-type semiconductor region 34 for reducing the resistance of the surface of the p-type punch-through layer 33. The p-type punch-through layer 33 is a conductive layer for coupling the source to the substrate 21. Another characteristic feature of the LDMOSFET of the present embodiment is that the p-type punch-through layer 33 is formed of a conductive layer comprised of a p-type polysilicon film buried in each of trenches 35 formed in the epitaxial layer 22.

In a conventional LDMOSFET, a punch-through layer is formed by implanting impurity ions into the epitaxial layer 22. A p-type punch-through layer formed by ion implantation has a drawback of a high parasitic resistance per unit area. However, by filling each of the trenches 35 with the p-type polysilicon film heavily doped with an impurity, the p-type punch-through layer 33 having a low parasitic resistance can be formed.

To respective upper portions of the p-type punch-through layer 33 (p⁺-type semiconductor region 34), the source (n⁺-type source region 31), and the drain (n⁺-type offset drain region 29) of each of the LDMOSFETs described above, plugs 39 in contact holes 38 formed in a silicon nitride film 36 and a silicon dioxide film 37 are coupled. The plugs 39 are each formed of a conductive film made mainly of a tungsten (W) film.

To the p-type punch-through layer 33 (p⁺-type semiconductor region 34) and the source (n⁺-type source region 31), a source electrode 40 is coupled via the plugs 39. To the drain (n⁺-type offset drain region 29), a drain electrode 41 is coupled via the plug 39. The source electrode 40 and the drain electrode 41 are each formed of a conductive film made mainly of an aluminum (Al) alloy film.

To the source electrode 40 and the drain electrode 41, respective wires 44 are coupled via through holes 43 formed in a silicon dioxide film 42 covering the source electrode 40 and the drain electrode 41. The wires 44 are each formed of a conductive film made mainly of an Al alloy film. Over the wires 44, there is formed a surface protective film 45 including a laminated film of a silicon dioxide film and a silicon nitride film. At the back surface of the substrate 21, there is formed a source backside electrode 46 including, e.g., a nickel (Ni) film, a titanium (Ti) film, or a laminated film of an Ni film and a gold (Au) film.

The semiconductor chip IC1 having the power amplifier PM formed therein is mounted over the module substrate with the main surface thereof facing upward (face-up mounting). The external terminals of the semiconductor chip IC1 and the substrate-side terminals formed over the component mounting surface of the module substrate are electrically coupled by bonding members, e.g., the bonding wires BW comprised of, e.g., Au thin wires.

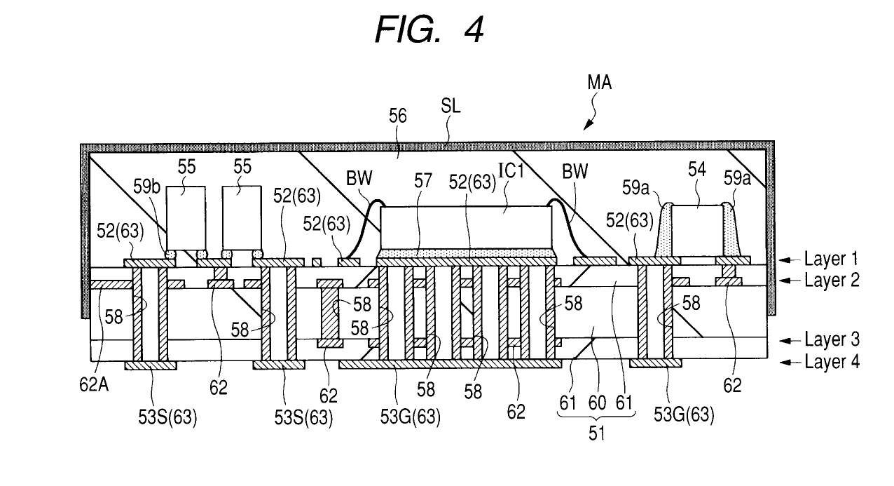

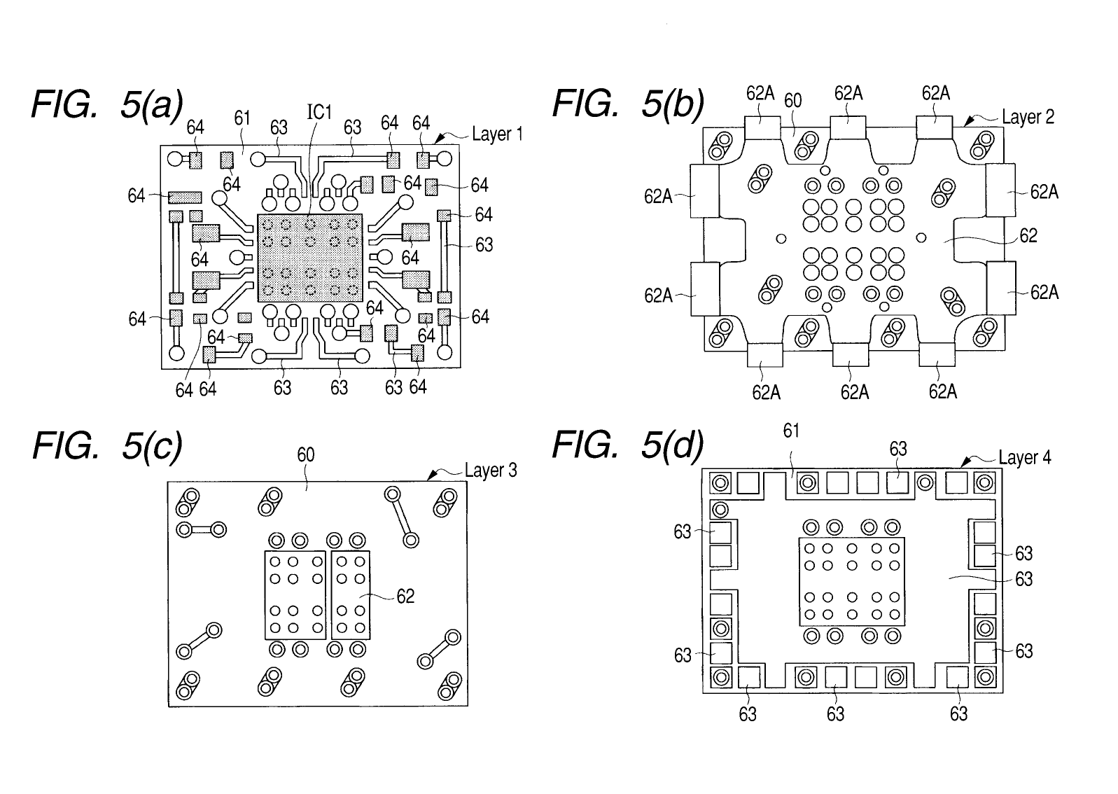

Next, a description will be given of a structure of the module MA after primary mounting by which surface mounted components are mounted over the module substrate. FIG. 4 is a main surface cross-sectional view showing an example of the primary mounting of the module MA according to the present embodiment. FIGS. 5(a) to 5(d) are principal-portion plan views of each of a plurality of insulator plates for illustrating a module substrate having a multilayer wiring structure, and formed integrally by laminating the insulator plates. Here, the structure of the module MA is such that the front end device 1 and the power amplifier PM, each described above, have been assembled into one module MA, but it will be easily appreciated that the structure of the module MA is not limited thereto. For example, the front end device 1 and the power amplifier PM may also be formed as discrete RF modules. Here, the description will be given using, as an example, the semiconductor chip IC1 having the power amplifier PM in which the amplification stages are formed of the LDMOSFETs. However, a semiconductor chip having a power amplifier in which amplification stages are formed of HBTs may also be used.

As shown in FIG. 4, in the module MA, a printed circuit board (PCB) having a multilayer wiring structure obtained by, e.g., integrally laminating a plurality of insulator plates is used as a module substrate 51. Over the component mounting surface of the module substrate 51, substrate-side terminals 52 each comprised of, e.g., a copper (Cu) film, wires, and the like are formed in a pattern. Over the back surface of the module substrate 51, electrodes 53G and 53S each comprised of, e.g., a Cu film are formed in a pattern.

FIG. 4 illustrates, as the surface mounted components mounted over the component mounting surface of the module substrate 51, the semiconductor chip IC1 in which active elements are formed, a single-element chip component 54 in which one passive element is formed over one chip substrate, and integrated chip components 55 in each of which a plurality of passive elements are formed over one chip substrate. In the semiconductor chip IC1, the power amplifier PM described above is formed. The plurality of external terminals formed over the main surface of the semiconductor chip IC1 are coupled to the substrate-side terminals 52 of the module substrate 51 corresponding thereto by bonding members. Here, as the bonding members, the bonding wires BW comprised of Au thin wires are used.

Further, the surface mounted components are covered with a high-elasticity resin 56 for molding. For example, the resin 56 is a high-elasticity epoxy resin, and the tolerable range of the elasticity thereof is not less than 2GPa at a temperature of not less than 180° C. Additionally, over the surfaces (upper and side surfaces) of the resin 56 and over parts of the side surfaces of the module substrate 51, there is formed a shield layer SL.

The semiconductor chip IC1 has the back surface thereof bonded to the substrate-side terminals 52 for mounting a chip formed over the component mounting surface of the module substrate 51, and is fixed to the upper surface of the module substrate 51 using a solder 57 as a die bonding material. As the solder 57, a high-melting-point solder which is liquefied at a temperature of, e.g., not less than 280° C., e.g., a lead (Pb)-tin (Sn) alloy is used. It is considered that a proper range of the content of Sn in a Pb—Sn solder is from, e.g., 2 to 30 wt % (It will be understood that the content of Sn is not limited to the range depending on other conditions). It is also considered that a range of the content of Sn which is appropriate for mass production is from 2 to 10 wt %, and a range around a center value of 10 wt % is most preferred. By using the high-melting-point solder, even when a large amount of heat is generated, an adhesion strength between the semiconductor chip IC1 and the module substrate 51 can be ensured. Therefore, it is possible to prevent the peeling of the semiconductor chip IC1 from the module substrate 51.

A backside electrode (e.g., the source backside electrode 46 of FIG. 3 described above) of the semiconductor chip IC1 is electrically and thermally bonded to the electrode 53G formed at the back surface of the module substrate 51 through the conductive material within a plurality of heat dissipation vias 58 formed to extend from the component mounting surface of the module substrate 51 to the back surface thereof through the module substrate 51. To the electrode 53G, a reference potential (e.g., about 0 V at the ground potential GND) is supplied. That is, the reference potential supplied to the electrode 53G at the back surface of the module substrate 51 is supplied to the back surface of the semiconductor chip IC1 through the heat dissipation vias 58 and the substrate-side terminals 52. Conversely, heat generated during the operation of the semiconductor chip IC1 is transmitted from the back surface of the semiconductor chip IC1 to the electrode 53G at the back surface of the module substrate 51 through the substrate-side terminals 52 and the heat dissipation vias 58 so as to be released. The electrode 53S formed at the back surface of the module substrate 51 and in the vicinity of the outer periphery thereof is an electrode for signal.

The single-element chip component 54 is a surface mounted component in which a passive element such as, e.g., a capacitor, an inductor, a resistor, or a ferrite bead is mounted over one chip substrate. The ferrite bead is an element having a structure in which an internal electrode for energization is buried in a ferrite element, and ferrite functions as a magnetic substance to absorb an RF current component causing electromagnetic interference (EMI) noise. The single-element chip component 54 is mounted over the module substrate 51 with the back surface thereof opposing the component mounting surface of the module substrate 51. The coupling terminals formed at the both ends of the single-element chip component 54 are solder coupled to the substrate-side terminals 52 formed over the component mounting surface of the module substrate 51 via a solder 59a. For the solder coupling, a Pb-free solder not containing Pb, e.g., a Sn-3Ag-0.5Cu solder (where Ag is silver) is used. The distance between the back surface of the single-element chip component 54 and the component mounting surface of the module substrate 51 is, e.g., about 10 μm, and the clearance therebetween is filled with the resin 56 for molding without the formation of a void.

The integrated chip components 55 are surface mounted components in each of which a plurality of passive elements such as, e.g., the lowpass filters LPF1 and LPF2 are formed over one chip substrate. The integrated chip components 55 are flip-chip coupled to the module substrate 51 with the main surfaces thereof facing the component mounting surface of the module substrate 51. Coupling terminals formed over the main surfaces of the integrated chip components 55 are solder coupled to the substrate-side terminals 52 formed over the component mounting surface of the module substrate 51 via solders 59b. For the solder bonding, a Pb-free solder not containing Pb, e.g., a Sn-3Ag-0.5Cu solder is used. The distances between the main surfaces of the integrated chip components 55 and the component mounting surface of the module substrate 51 are in a range of, e.g., about 10 to 20 μm, and the clearance therebetween is also filled with the resin 56 for molding without the formation of a void.

It has been stated that, as a solder material used for the solder coupling of the single-element chip component 54 and the integrated chip components 55, a Pb-free solder is used. However, the solder material is not limited thereto, and various solder materials can be used instead. For example, Sn containing Pb (hereinafter referred to as a Pb—Sn solder) may also be used. However, if a consideration is given to Pb control in Europe, a Pb-free solder is preferred.

Since the bonding wires BW are used in the semiconductor chip IC1, a plating film is formed over the surface of each of the substrate-side terminals 52. The plating film includes a laminated film of, e.g., an Ni layer and an Au film which are formed successively in an ascending order by a plating method. As a result, the single-element chip component 54 is solder coupled to the plating film at the coupling terminals thereof, and the integrated chip components 55 are coupled to the plating films at the coupling terminals thereof, while the bonding wires BW coupled to the external terminals formed over the main surface of the semiconductor chip IC1 are coupled to the plating films over the surfaces of the substrate-side terminals 52.

The module substrate 51 is formed of a core material 60, and an insulating material called pre-pregs 61 between which the core material 60 is vertically interposed. Above and below the core material 60, inner-layer Cu films 62 (in second- and third-layer wiring Layers 2 and 3) are formed in a pattern, and interposed between the pre-pregs 61 described above. FIG. 5(b) shows an example of a wiring pattern (in the second-layer wiring Layer 2) of the inner-layer Cu films 62 formed between the portions of the core material 60 closer to the component mounting surface of the module substrate 51 and the pre-preg 61. FIG. 5(c) shows an example of a wiring pattern (in the third-layer wiring Layer 3) of the inner-layer Cu films 62 formed between the portions of the core material 60 closer to the back surface of the module substrate 51 and the pre-preg 61. The thickness of each of the inner-layer Cu films 62 is, e.g., about 0.02 mm. The thickness of each of the pre-pregs 61 is, e.g., about 0.06 mm.

Further, at the outer surface of the pre-preg 61 closer to the component mounting surface, outer-layer Cu films (in a first-layer wiring Layer 1) such as the substrate-side terminals 52 and the wires that have been described above are formed in a pattern in close contact with the pre-preg 61. FIG. 5(a) shows an example of a wiring pattern (in the first-layer wiring Layer 1) of outer-layer Cu films 63 formed over the outer surface of the pre-preg 61 closer to the component mounting surface of the module substrate 51, and an example of the placement of the surface mounted components mounted over the component mounting surface, e.g., the semiconductor chip IC1 and chip components 64 (including the single-element chip component 54 and the integrated chip components 55 which have been described above). At the outer surface of the pre-preg 61 closer to the back surface, the outer-layer Cu films (in a fourth-layer wiring Layer 4) for the electrodes 53G and 53S described above are formed in a pattern in close contact with the pre-pregs 61. FIG. 5(d) shows an example of a wiring pattern (in the fourth-layer wiring Layer 4) of the outer-layer Cu films 63 formed outside the pre-preg 61 closer to the back surface of the module substrate 51. The thickness of each of the outer-layer Cu films 63 is, e.g., about 0.02 mm.

Over the surface of each of the outer-layer Cu films 63, there is formed a plating film having a laminated structure in which, e.g., an Ni layer and an Au layer are formed successively in an ascending order by a plating method. Further, the upper surface of each of the outer-layer Cu films 63 is covered with a solder resist (the depiction thereof is omitted) except for a region where the surface mounted components such as the semiconductor chip IC1 and the chip components 64 are mounted. The thickness of the solder resist is in a range of, e.g., about 0.025 to 0.05 mm.

Between the inner-layer Cu films 62 in two layers (between the second- and third-layer wirings Layers 2 and 3) located above and below the core material 60 or between the inner-layer Cu films 62 and the outer-layer Cu films 63 (between the first- and second-layer wirings Layers 1 and 2 or between the third- and fourth-layer wirings Layers 3 and 4), electrical coupling is provided via the heat dissipation vias 58 in each of which the Cu film has been buried to extend through the core material 60 or the pre-preg 61. The core material 60, the pre-pregs 61, and the solder resist are each comprised of a resin such as, e.g., epoxy.

Parts (parts shown by inner-layer Cu wires 62A in FIG. 5(b)) of the second-layer wiring Layer 2 shown in FIG. 5(b) are formed extensively to the outer periphery of the core material 60, and are electrically coupled to the shield layer SL. The inner-layer Cu wires 62 and 62A electrically coupled to the shield layer SL are ground wiring, and electrically coupled to the wiring pattern (in the fourth-layer wiring Layer 4) of the outer-layer Cu films 63 formed outside the pre-preg 61 closer to the back surface via the heat dissipation vias 58 formed in the core material 60 and the pre-pregs 61.

The shield layer SL is formed by an electroless plating method. The electroless plating method allows selective precipitation of a plating film at a catalyst active surface without using an external power source. For example, as stated in “Electroplating Handbook” edited by Electroplating Research Society Japan and published by Nikkan-Kogyo Shinbun in 1986, in an autocatalytic electroless Cu plating method, a Cu precipitation reaction is continued by an oxidation reaction of a reductant. In addition, treatment with an activation solution containing Pd allows uniform formation of a plating film even over a non-conductive material such as a mold resin and over a portion having a complicated shape. As a result, it is possible to form a uniform shield layer SL even over the surfaces (upper and side surfaces) of the resin 56 molding therein the surface mounted components mounted in the module MA by an electroless plating method. Therefore, a desired shielding effect can be obtained with a minimum required metal material, which is advantageous in terms of reducing the cost of a product.

In the present embodiment, the shield layer SL includes a laminated film of a first film formed by an electroless plating method, and having an electromagnetic shielding function, e.g., a Cu film and a second film formed over the Cu film by an electroless plating method, and having an anticorrosive function, e.g., an Ni film. Hereinbelow, a description will be given of the various effects of the shield layer SL including a laminated film of a Cu film and an Ni film (hereinafter referred to as a Cu/Ni laminated film) each formed by an electroless plating method.

### <First Effect (Water Vapor Permeability)>

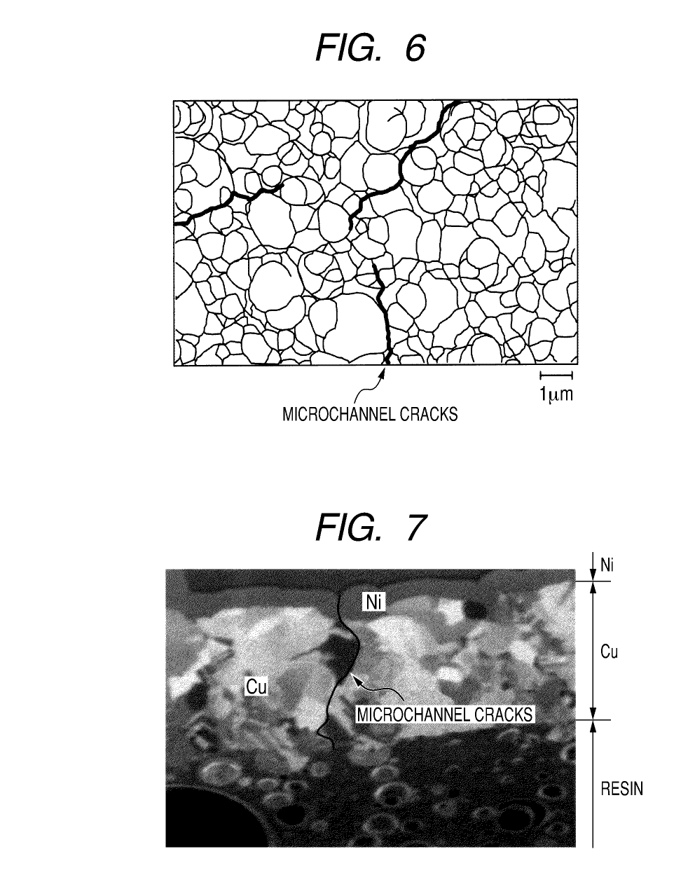

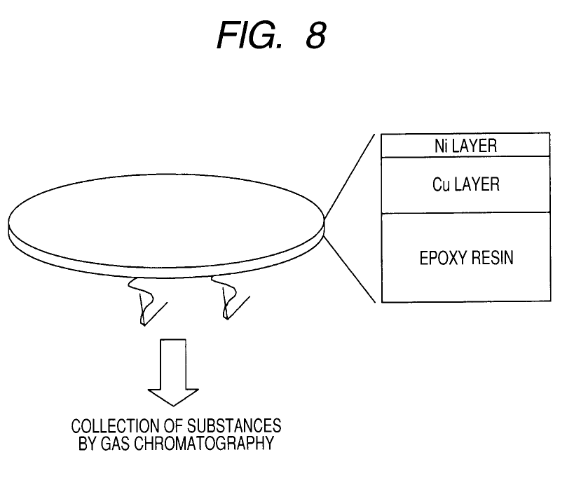

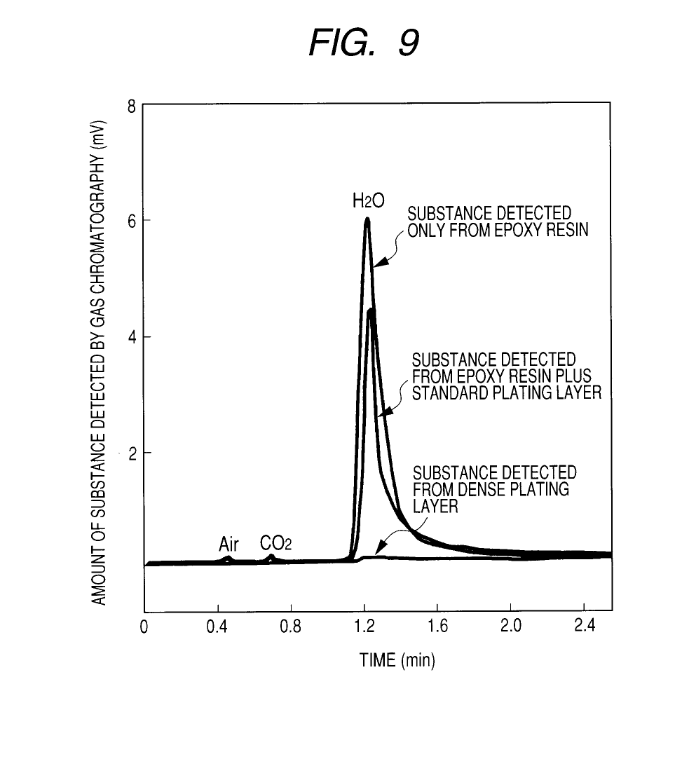

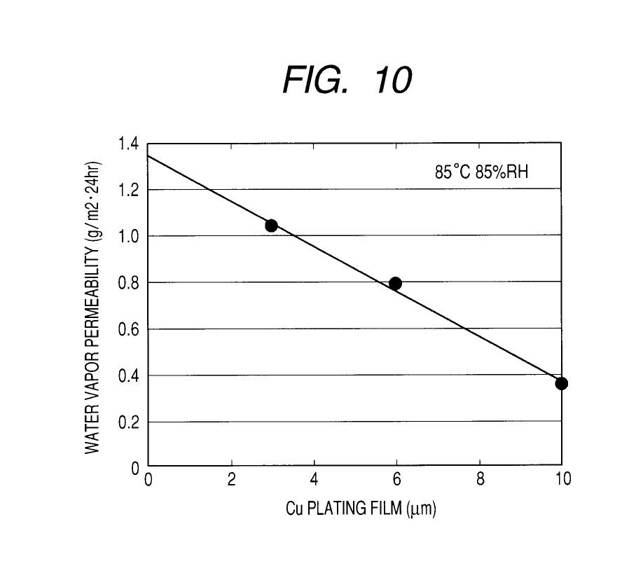

The water vapor permeability of the shield layer including the Cu/Ni laminated film will be described using FIGS. 6 to 10. FIG. 6 is a surface diagram of the shield layer. FIG. 7 is a cross-sectional photograph of the shield layer. FIG. 8 is an illustrative view of a sample for which the water vapor permeability of the shield layer is measured. FIG. 9 is a graph showing the result of measuring the water vapor permeability of the shield layer. FIG. 10 is a graph showing the relationship between the water vapor permeability of the shield layer and the thickness of the shield layer.

As shown in FIGS. 6 and 7, in the shield layer SL, a plurality of microchannel cracks each having a width of not more than 100 nm (a width of typically 1 to 60 nm) are randomly present along crystal boundaries and in a net-like configuration without being coupled to each other in a straight line. As shown in FIG. 7, the plurality of microchannel cracks present along the grain boundaries form a plurality of paths extending from the resin to the surface of the shield layer.

The microchannel cracks are formed in a heating step performed after the formation of the Cu/Ni laminated film by the electroless plating method. For example, when heating is performed at 150° C. for one hour, holes through which hydrogen leaks out, which were observed in the Ci/Ni laminated film immediately after the formation thereof by the electroless plating method, are closed, and minute crystal grains in the surface of the Ni plating film are coarsened. This causes a change in a crystalline state, and smoothens the surface of the Ni plating film to result in the formation of the microchannel cracks. The smoothening of the surface of the Ni plating film also improves the corrosion resistance of the surface of the Ni plating film. The temperature and the time in the heating step described above are only exemplary, and are not uniquely determined.

FIGS. 9 and 10 are graphs illustrating the water vapor permeability of the shield layer measured using the sample shown in FIG. 8. For the measurement, a method for measuring a water vapor permeability (JISk-7129-3 (gas chromatographic method) or ISO15105-1 (gas chromatographic method)) was used. For example, a circular disc (having a thickness of, e.g., 0.55 mm and a radius of, e.g., 56 mm) of an epoxy resin having a thickness equal to that of an epoxy resin used in an electronic component or the like was produced. Over the epoxy resin circular disc, a Cu film having a thickness ranging from 2 to 10 μm was deposited by an electroless plating method. Further, over the Cu film, an Ni film having a thickness of 0.25 μm was deposited by an electroless plating method, thereby providing samples to be used for the measurement. The measurement was performed in a water vapor atmosphere under temperature and humidity conditions of 85° C. and 85% (equivalent to a relative humidity). The water vapor permeability is also measurable even in a water vapor atmosphere under other temperature and humidity conditions such as 30° C. and 90% (equivalent to a relative humidity), which are typical measurement conditions for a plastic film.

FIG. 9 shows the result of measurement of the water vapor permeability of the Cu/Ni laminated film (a Cu plating film having a thickness of 3 μm plus an Ni plating film having a thickness of 0.25 μm) performed in a water vapor atmosphere at a temperature of 85° C. and a humidity of 85%. In FIG. 9, the standard plating film indicates the Cu plating film, and the dense plating film indicates the Ci/Ni laminated film. With the lapse of time, air, carbon dioxide, and moisture that had passed through the epoxy resin and the Cu/Ni laminated film were detected. After sufficient time had elapsed, from the sample including only the epoxy resin after the lapse of, e.g., a one-hour sampling time, a water vapor permeability of 1.88 g/m²-24 h was obtained. However, the water vapor permeability of the sample in which the Cu/Ni laminated film had been formed over the epoxy resin was lower than the water vapor permeability of the sample including only the epoxy resin. From the sample in which the thickness of the Cu plating film was 3 μm, a water vapor permeability of 1.04 g/m²-24 h was obtained

As shown in FIG. 10, the relationship between the water vapor permeability and the thickness of the Cu plating film is such that, as the thickness of the Cu plating film increases, the water vapor permeability gradually decreases. From the sample in which the thickness of the Cu plating film was 6 μm, a water vapor permeability of 0.79 g/m²-24 h was obtained. From the sample in which the thickness of the Cu plating film was 10 μm, a water vapor permeability of 0.36 g/m²-24 h was obtained. This is because, even when the thickness of the Cu plating film becomes large, there are microchannel cracks by which water vapor is permeated in the direction of depth of the shield layer. Actually, in an electronic component provided with a shield layer, water vapor leaks out when the temperature of the electronic component is not less than 100° C. In the Cu/Ni laminated film, the widths of the microchannel cracks increase as the temperature rises up to a temperature in the vicinity of 260° C., and water vapor is more likely to leak out.

### <Second Effect (Electromagnetic Shielding Effect)>

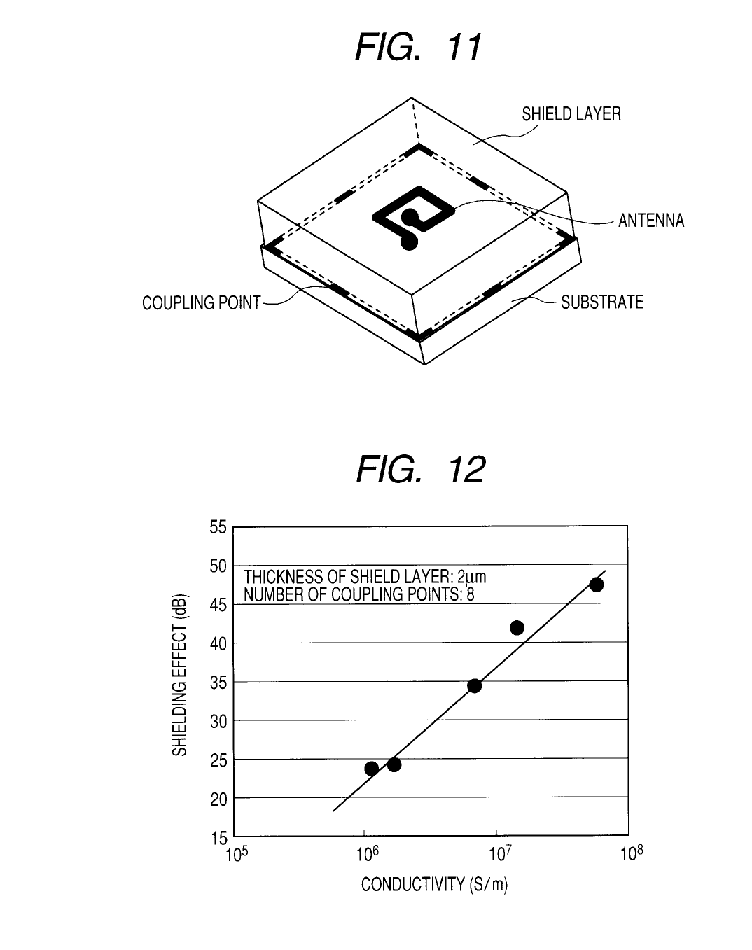

The thickness of a material required by the shield layer including the Cu/Ni laminated film will be described with reference to FIGS. 11 to 13.

In a mobile phone, the surface of an electronic component is covered with a conductive shield layer to be shielded from an electromagnetic wave. This causes reflection, absorption, or multiple reflection of the electromagnetic wave and thereby allows attenuation of the energy thereof. Here, a skin depth d of the shield layer can be represented by a distance over which an electromagnetic field incident on the shield layer is attenuated to 1/e (where e is a natural logarithm of about −8.7 dB), and given by (Expression 1) shown below (see, e.g., “SIGNAL INTEGRITY, 2004, Publishing as Prentics Hall Professional Reference, pp. 189-197”).

d=(2/(ωμs))^{1/2},(μ=μₛμ₀) (Expression 1)

wherein ω represents a frequency, μ represents a magnetic permeability, μₛ represents a relative magnetic permeability, and μ₀ represents a dielectric constant of a free space (4π×10⁻⁷ [H/m]). When the skin depth d of Cu at a frequency of 1 GHz was calculated using (Expression 1) and the conductivity (5.82×10⁷ S/m) of Cu, the result of the calculation was 2

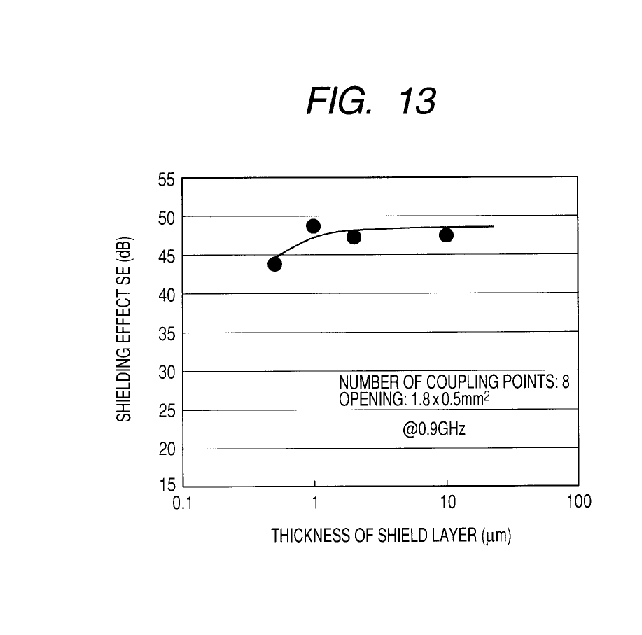

FIG. 11 shows a schematic view of a simulation model used in verifying the electromagnetic shielding effect. In the simulation model, based on the foregoing result, the thickness of a shield layer shielding the surface of an RF module of a size of 8 mm×8 mm was set to 2 μm, the shield layer and the ground wiring of a substrate are coupled to each other at eight points, and an antenna equivalent to the circuit was placed at the center thereof. The result of simulation of an electromagnetic shielding effect when the model was caused to transmit signals at a frequency of 0.9 GHz is shown in FIGS. 12 and 13.

FIG. 12 is a graph showing the relationship between the electromagnetic shielding effect and the conductivity obtained by the simulation using the simulation model (in which the thickness of the shield layer was 2 μm) shown FIG. 11 described above. As the resistance of the shield layer is lower, the shielding effect is higher, and the shielding effect is substantially proportional to the logarithm of the conductivity of the shield layer. If a consideration is given to the effective use of the shield layer, as long as the thickness of the shield layer is the same, the shield layer having a higher conductivity provides a higher shielding effect. Based on the result, a Cu film having a high dielectric constant is used in the present embodiment.

FIG. 13 is a graph showing the electromagnetic shielding effect obtained by simulation when a Cu film was used in the shield film, and the thickness thereof was varied. As the thickness of the shield layer is increased, the electric resistance of the shield layer decreases. However, because an electromagnetic wave emitted from the antenna, and desired to be blocked cannot reach a depth deeper than the depth of skin of the shield layer, even when the thickness of the shield layer is increased to be not less than the depth of skin, the shielding effect remains the same. Therefore, it will be understood that the thickness of the shield layer needed to obtain a high shielding effect is sufficient as long as it is increased to about the depth of skin.

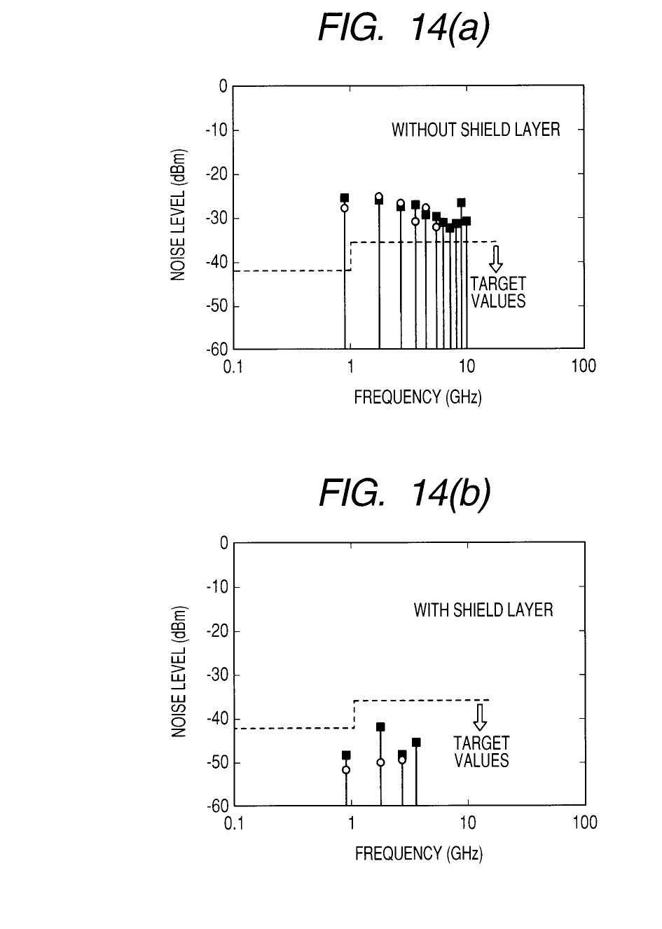

Next, the electromagnetic shielding effect will be described using FIGS. 14(a) and 14(b). FIGS. 14(a) and 14(b) are graphs respectively showing the relationship between an amount of noise generated in an RF module in which a shield layer is not formed over the surface of a resin and a frequency and the relationship between an amount noise generated in an RF module in which a shield layer is formed over the surface of a resin and a frequency. The target values are based on the Third Generation Partnership Project (3GPP) TS51.010-1 standard for mobile phone terminals. Measurement was performed based on the standard values. On each of the RF modules, a thermal shock test was performed (up to 1000 cycles each at −55 to 125° C. for 30 minutes), and then the relationships between the amounts of generated noise and the frequencies were examined. The thickness of a Cu plating film was set to 3 μm in consideration of thickness variations in mass production, and the thickness of an Ni plating film was set to 0.25 μm.

As shown in FIGS. 14(a) and 14(b), in the RF module not provided with the shield layer, the target values (3GPP standard values) could not be achieved at any of the frequencies at which the measurement was performed. By contrast, in the RF module provided with the shield layer, the target values were achieved at all the frequencies at which the measurement was performed, and it could be verified that the shield layer was able to provide the electromagnetic effect.

As a JEDEC LEVEL2 moisture absorption test, after moisture absorption at a temperature of 85° C. and a relative humidity of 85% for 168 hours, reflow heating at 260° C. (sustained at a temperature of not less than 260° C. for 60 seconds) was performed. However, swelling did not occur in the resins and the shield layers.

Further, because a plating film has a spreading property, it can be considered that the RF module provided with the shield layer formed by an electroless plating method can provide a high electromagnetic shielding effect. Specifically, even when thermal deformation occurs during the reflow heating and actual operation of the RF module, and a stress is concentrated on a portion due to the difference between the respective linear expansion coefficients of a plating film and a component material, it is possible to inhibit the occurrence of the peeling, fracture, and cracking of the plating film at the portion.

In addition, not wires in the lowermost layer provided at the back surface of the module substrate, but a wiring layer (e.g., the inner-layer Cu wires 62 and 62A shown in FIGS. 4 and 5(b) described above) which is a part of inner-layer wiring provided inside the module substrate, and other than the wires in the lowermost layer is used as the ground wiring. Furthermore, the major portion of the inner-layer wiring is used as the ground wiring, while the peripheral portion of the inner-layer wiring is extended to the outer periphery of the module substrate, and electrically coupled to the shield layer. By providing the module substrate with such a structure, coupling portions between the ground wiring of the module substrate and the shield layer can be easily provided at short intervals. This allows the provision of a large number of the coupling portions, and reduces a grounding inductance. As a result, it is possible to maintain a sufficient electromagnetic shielding effect.

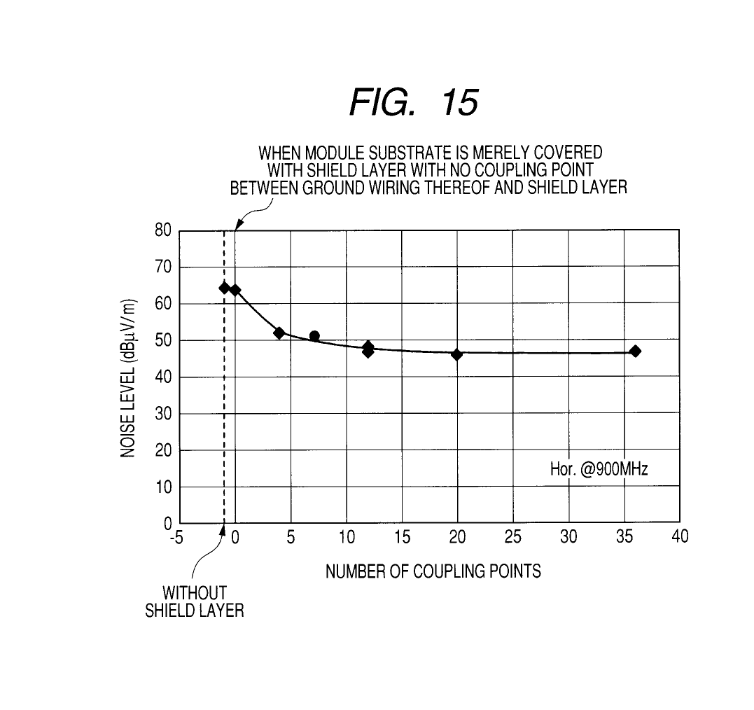

FIG. 15 shows a graph illustrating the relationship between a noise level and the number of the coupling portions (number of coupling points) between the ground wiring of the module substrate and the shield layer. As shown in FIG. 15, it can be seen that, as the number of coupling points between the ground wiring and the shield layer increases, the noise level decreases and, as the number of coupling points is increased by reducing the intervals between the coupling portions, a higher electromagnetic shielding effect is obtainable.

Therefore, the RF module provided with the shield layer formed by the electroless plating method retains the electromagnetic shielding effect, and has, even when a stress is concentrated on a portion due to thermal deformation or drop impact, a stress reducing function with respect to the stress concentrated portion.

In general, in components actually mounted in a mobile phone or the like, materials forming the components thermally expand due to the difference between a temperature when the phone is operating and a temperature when the phone is not operating and, due to the difference between the respective thermal expansion coefficients of the components, a stress and a strain repeatedly occur at a predetermined location in the components so that a stress fracture resulting therefrom occurs. However, since the structure of the plating film of the present invention has the stress reducing function even against such a thermal fatigue fracture, local peeling and fracture of the plating film do not occur in a coupling portion with an electrode, a corner portion of the module, or the like, and sufficient reliability is ensured.

### <Third Effect (Recognition of Laser Marked Character)>

Since the plating film follows a laser marked character (having a thickness of 150 to 300 μm) in a trench shape inscribed in the surface of the resin, the laser marked character can be recognized even after plating. As described above, in the laminated film of the Cu plating film having a thickness of, e.g., 3 μm and the Ni plating film having a thickness of, e.g., 0.25 μm, the electromagnetic shielding effect is obtainable. Therefore, it is possible to form a shield layer having an electromagnetic shielding effect without erasing the laser marked character. In addition, since a highly versatile laser marker for epoxy-based resin molding can be used without alterations, it is possible to inhibit an increase in manufacturing cost.

### <Fourth Effect (Deposition of Films of Shield Layer)>

The shield layer is formed by the electroless plating method, and the formation of an external electrode, an electrode, and the like exclusively for the shield layer is unnecessary. Therefore, even when the sizes of the module substrate and the surface mounted components are changed, it is possible to form a shield layer of a constantly uniform material and a constantly uniform thickness, and obtain a stable electromagnetic shielding effect.

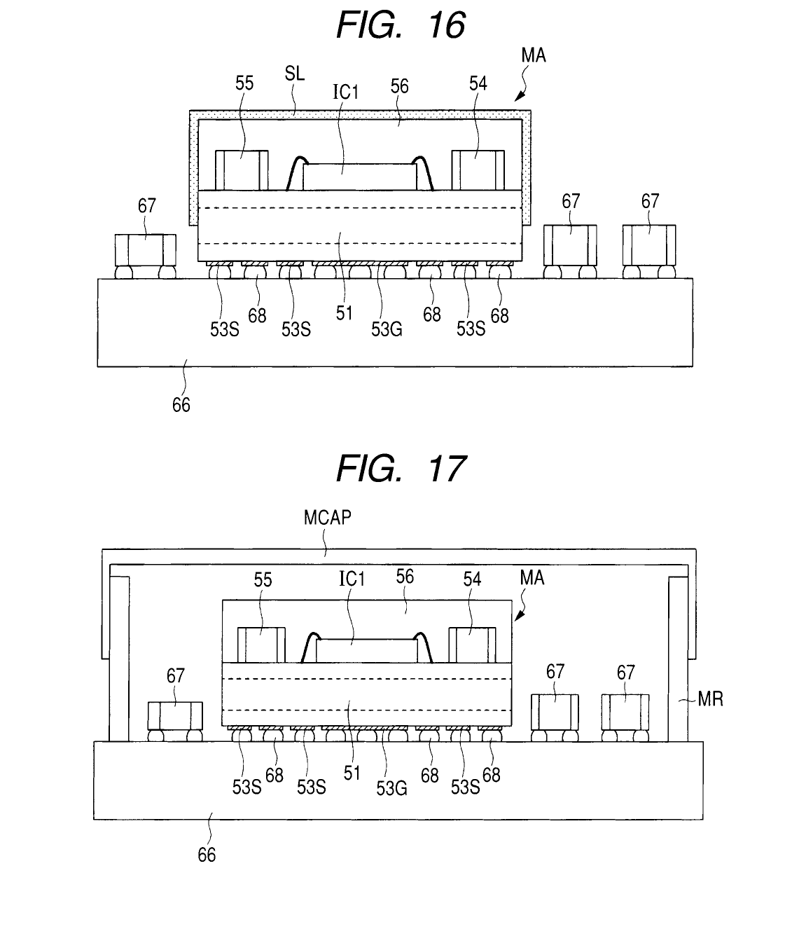

Next, a description will be given of a structure of the module MA after secondary mounting by which the module MA described above is further mounted over a mounting wiring substrate (mother board) so as to be incorporated in a product. FIG. 16 is a principal-portion schematic view of an example of a semiconductor device in which the module MA is secondary mounted according to the present embodiment. FIGS. 17 to 19 are principal-portion schematic views showing an example of a semiconductor device in which a conventional module MA is secondary mounted.

As shown in FIG. 16, a mother board 66 is comprised of, e.g., a printed wiring substrate having a multilayer wiring structure. Over the main surface of the mother board 66, the module MA and a plurality of chip components 67 are mounted. As described above, in the module MA, the module substrate 51 is applied to the substrate thereof, and the component mounting surface of the module substrate 51 is covered with the resin 56 with which the semiconductor chip Id1, the single-element chip component 54, and the integrated chip components 55 are molded. Further, over the surfaces (upper and side surfaces) of the resin 56, the shield layer SL having the water vapor permeability and the electromagnetic shielding effect is formed. The module MA is mounted over the main surface of the mother board 66 with the electrodes 53G and 53S formed at the back surface of the module substrate 51 facing the main surface of the mother board 66. The electrodes 53G and 53S described above are coupled to printed wires each formed over the main surface of the mother board 66 via a bonding material, e.g., solders 68.

Using FIGS. 17 to 19, a shield module using a metal cap will be described. FIG. 17 shows a principal-portion schematic view of a semiconductor device when the module MA is shielded using the metal cap. In the case of using a metal cap MCAP, each of the module MA mounted over the main surface of the mother board 66 and the plurality of other chip components 67 should be covered with the metal cap MCAP. Therefore, it is necessary to form a metal ring MR for fixing the metal cap MCAP (for causing the metal cap MCAP to fit therein) around the main surface of the mother board 66. By contrast, in the secondary mounting according to the present embodiment, a region where the metal ring MR is to be formed is unnecessary. Accordingly, the plan view area of the mother board 66 can be reduced to a value smaller than in the case of using the metal cap MCAP. This reduces the plan view area of the semiconductor device and also reduces the height thereof, thereby allowing a reduction in the size of the semiconductor device.

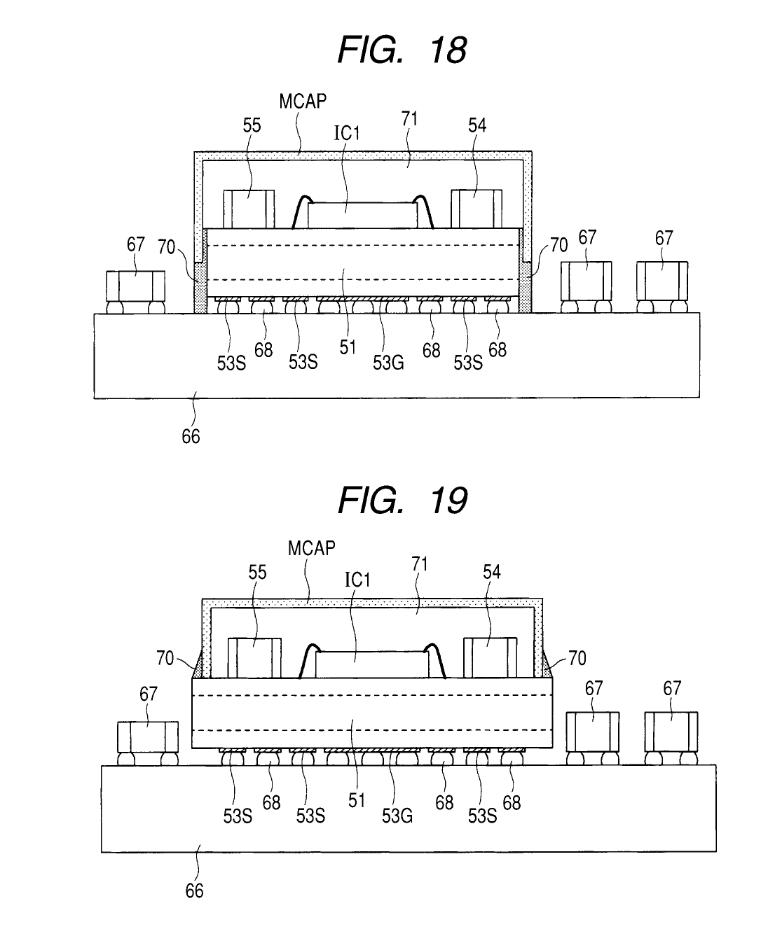

FIG. 18 shows a cross-sectional view when the metal cap provided on a per module basis is directly coupled to the ground terminal of the mother board. FIG. 19 shows a cross-sectional view when the metal cap of each of the modules is directly coupled to the ground terminal disposed around the module substrate. Reference numerals 70 and 71 shown in FIGS. 18 and 19 respectively denote a solder and a space. In either case, the metal cap MCAP is coupled using the solder so that it is necessary to ensure a terminal area for solder bonding over the mother board or over the module substrate. Therefore, a region where the metal cap is solder bonded is needed over the mother board around a region where the RF module is mounted or over the module substrate, which cooperates with the thickness of the metal cap to inhibit a reduction in the size of the module.

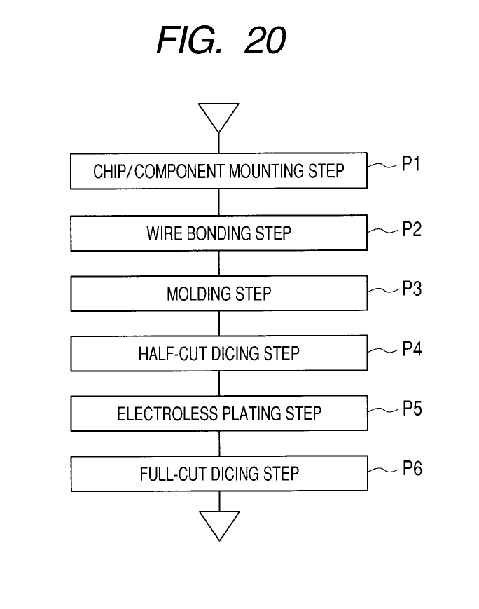

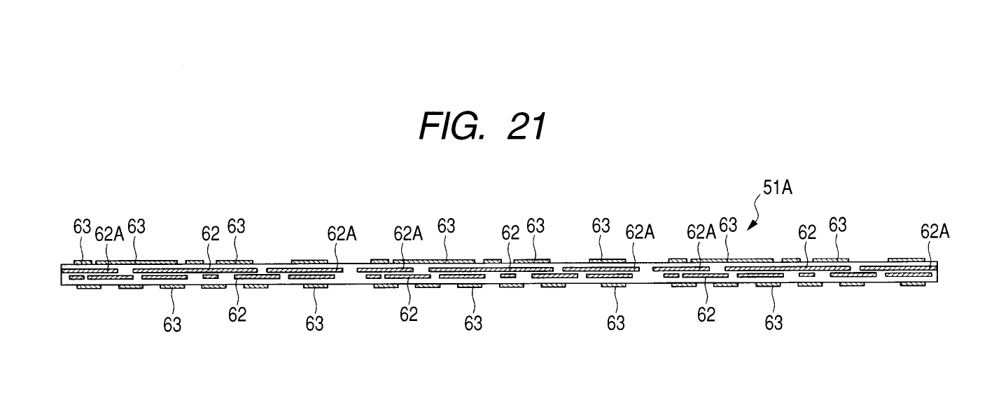

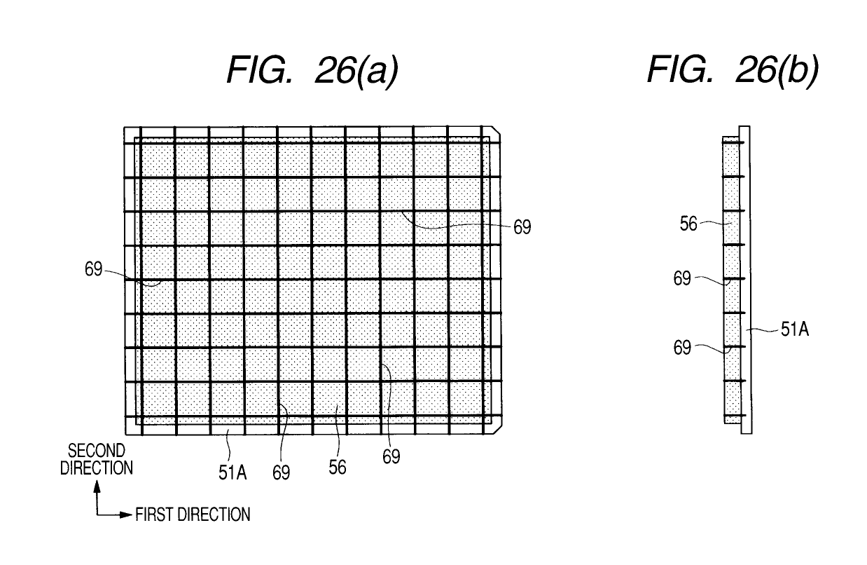

Next, an example of the primary and secondary mounting steps of the module MA according to the present embodiment will be described in this order using FIGS. 20 to 28. FIG. 20 is a process step view illustrating the procedure of assembly of the module MA. FIGS. 21 to 25, 27, and 28 are principal-portion cross-sectional views of a semiconductor device showing three module regions. FIGS. 26(a) and 26(b) are a principal-portion plan view and a principal-portion cross-sectional view of the semiconductor device, each of which shows the entire module regions.

The primary mounting step of the module MA will be described.

First, a first wiring substrate 51A shown in FIG. 21, e.g., is prepared. The first wiring substrate 51A is a multi-module substrate in which a plurality of (e.g., about eighty) module regions as device regions are formed and defined by partitioning lines. In the case where, e.g., eighty module regions are formed, an example of the dimensions thereof is about 90 mm×75 mm, and an example of the thickness thereof is about 0.4 mm.

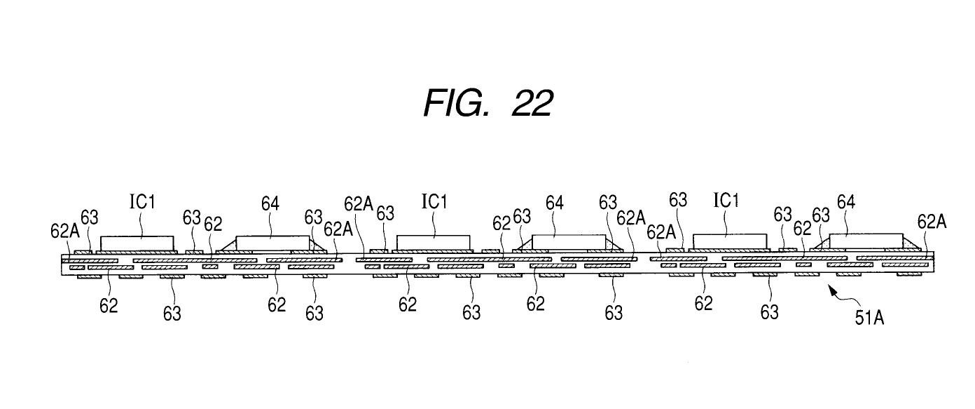

Next, as shown in FIG. 22, a solder paste is printed over the outer-layer Cu wires 63 (substrate-side terminals 52) coupled to the semiconductor chip IC1 and the chip components 64 (including the single-element chip component 54 and the integrated chip components 55), and then the semiconductor chip IC1 and the chip components 64 are disposed over the predetermined outer-layer Cu wires 63. Subsequently, reflow heating and flux cleaning are performed and, by melting the solder, the semiconductor chip IC1 and the chip components 64 each described above are collectively solder coupled (chip/component mounting step P1 of FIG. 20). Instead of the solder paste, an adhesive paste containing metal flakes can also be used. Here, the chip components 64 mounted with the back surfaces thereof opposed to the main surface of the first wiring board 51A are depicted, but the chip components mounted with the upper surfaces thereof opposed to the main surface of the first wiring board 51A are also simultaneously solder coupled.

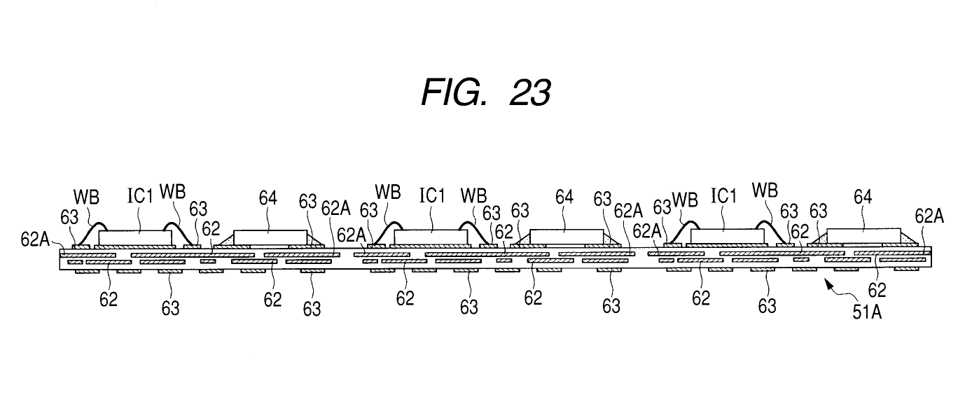

Next, wire bonding is performed (wire bonding step P2 of FIG. 20). Here, as shown in FIG. 23, the plurality of external terminals exposed at the upper surface of the semiconductor chip IC1 and the outer-layer Cu wires 63 having plating films formed over the surfaces thereof are coupled to each other using the bonding wires BW, e.g., Au wires.

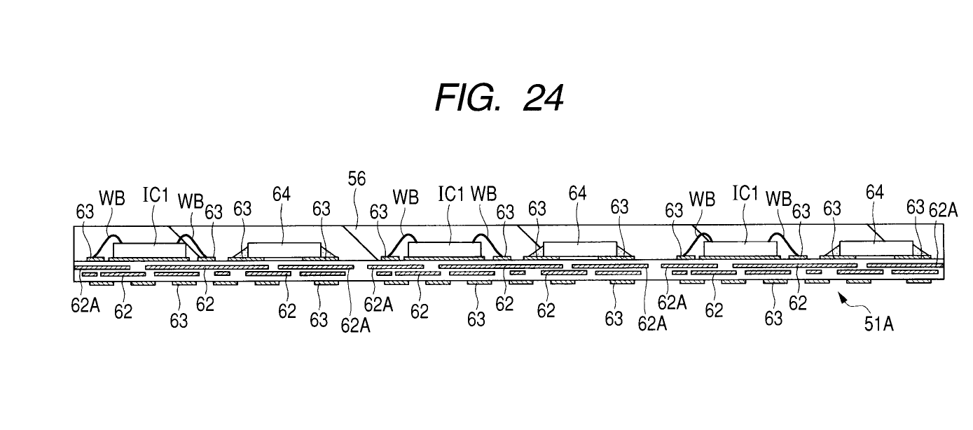

Next, as shown in FIG. 24, transfer molding (mold step P3 of FIG. 20) which molds the semiconductor chip IC1 and the chip components 64 with the resin 56 is performed. First, the upper die of a molding device is raised, and the first wiring substrate 51A solder coupled to the semiconductor chip IC1 and to the chip components 64 is placed in the lower die thereof. Thereafter, the upper die is lowered to fix the first wiring substrate 51A. In the upper die, an air bent for sending out air and a resin within a mold die and between the upper die and the lower die to the outside is provided. Subsequently, a pressure within the mold die is forcibly reduced to a level of, e.g., not more than 1 Torr. Thereafter, a resin tablet was heated with a pre-heater. After the viscosity of the resin is reduced, the liquefied resin 56 is sent under pressure into the mold die. For the resin 56, a thermosetting epoxy resin, e.g., is used. Subsequently, the molding resin filling the mold die is cured by a polymerization reaction. Then, the upper die and the lower die are opened, and the first wiring substrate 51A covered with the resin 56 is collected. Thereafter, the unneeded molding resin 56 is removed, and baking treatment is further performed to complete the polymerization reaction so that the semiconductor chip IC1 and the chip components 64 are molded with the resin 56.

Thus, by loading the mold die with the resin 56 after reducing the pressure within the mold die, it is possible to provide the resin 56 with fluidity. This allows small clearances, e.g., the clearance (of about 10 μm) between the back surface of the single-element chip component 54 and the component mounting surface of the first wiring substrate 51A and the clearances (in a range of about 10 to 20 μm) between the main surfaces of the integrated chip components 55 and the component mounting surface of the first wiring substrate 51A to be filled with the resin 56, while preventing the formation of a void. As a result, even when heat at a temperature of, e.g., about 260° C. is applied during the assembly of the module MA described next, and a Pb-free solder is half-molten, a flush-like flow of the Pb-free solder can be prevented. Accordingly, there is no coupling between, e.g., the coupling terminals at the both ends of the single-element chip component 54 or between the coupling terminals over the main surfaces of the integrated chip components 55, and a short circuit can be circumvented.

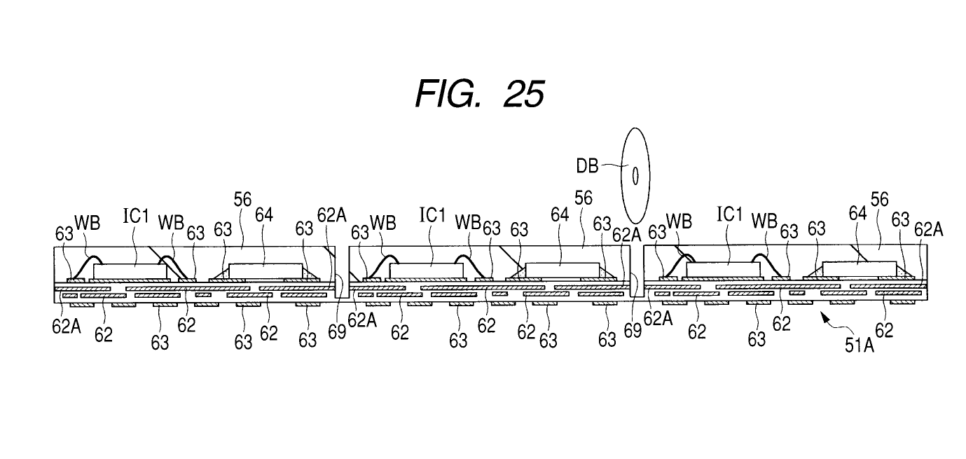

Next, as shown in FIGS. 25 and 26, the resin 56 and the first wiring substrate 51A are subjected to half-dicing along dicing lines provided in a first direction and a second direction orthogonal to the first direction using a dicing cutter DB (half-cut dicing step P4 of FIG. 20). Half-dicing is cutting by which the resin 56 and the first wiring substrate 51A are not completely cut, but incisions 69 are made down to a depth reaching the inner-layer Cu wires 62A which are parts of the ground wiring provided in the first wiring substrate 51A. As a result, the portions of the resin and the first wiring substrate 51A located below the inner-layer Cu wires 62A remain coupled. The inner-layer Cu wires 62 and 62A used as the ground wiring are in the second-layer wiring close to the component mounting surface of the first wiring substrate 51A.

Thereafter, in the upper surface of the resin 56, a trademark, a product name, a lot number, and the like, e.g., are inscribed on a per module-region basis.

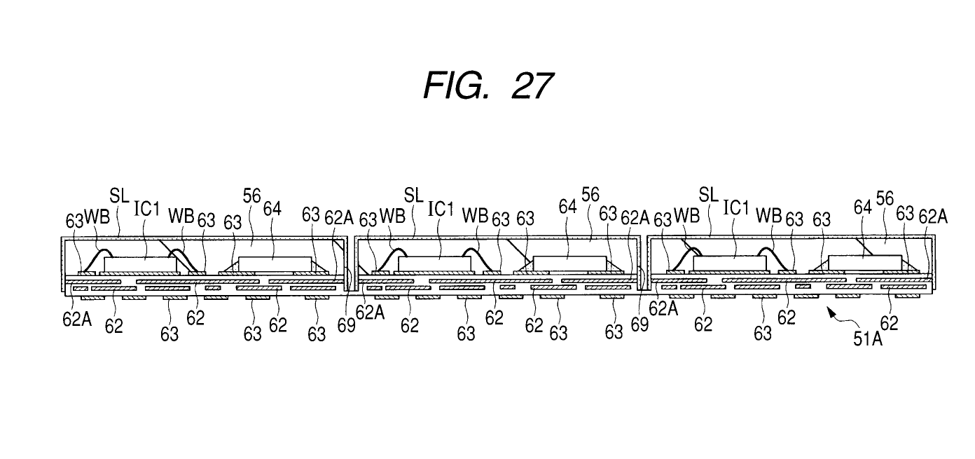

Next, as shown in FIG. 27, the shield layer SL is formed so as cover the inner-layer Cu wires 62A and the surfaces (upper and side surfaces) of the resin 56 which are exposed in the portions of the incisions 69 by an electroless plating method (plating step P5 of FIG. 20). Hereinbelow, the step of depositing the films of the shield layer SL will be sequentially described. (1) As a pre-etching process, the first wiring substrate 51A is dipped in a 70° C. solution mixture of aqueous sodium hydroxide (20 g/L) and an organic solvent (500 g/L) for 5 minutes, and then cleaned with water. (2) As a permanganate etching process, the target structure is dipped in a 80° C. solution mixture of potassium permanganate (50 g/L) and aqueous sodium hydroxide (20 g/L) for 5 minutes, and then cleaned with water. (3) As a neutralization process, the target structure is dipped in a 50° C. solution mixture of hydroxylamine (20 g/L) and concentrated sulfuric acid (50 ml/L) for 5 minutes, and then cleaned with water. (4) As a conditioning process, the target structure is dipped in a 60° C. ethanolamine (20 g/L) for five minutes, and then cleaned with water. (5) As a soft etching process, the target structure is dipped in a 25° C. solution mixture of sodium persulfate (150 g/L) and concentrated sulfuric acid (10 ml/L) for 2 minutes, and then cleaned with water. (6) As a preparatory dipping process, the target structure is dipped in concentrated hydrochloric acid (300 ml/L) at a room temperature for 1 minute, and then cleaned with water. (7) For catalyzation, the target structure is dipped in a 25° C. solution mixture of concentrated sulfuric acid (300 ml/L), palladium chloride (170 mg/L), and tin dichloride (10 g/L) for 3 minutes, and then cleaned with water. (8) For acceleration, the target structure is dipped in a 25° C. solution mixture of concentrated sulfuric acid (50 ml/L) and hydrazine (0.5 g/L) for 5 minutes, and then cleaned with water. (9) As electroless Cu plating, the target structure is dipped in a plating bath prepared by adjusting a 70° C. solution mixture of copper sulfate (10 g/L), EDTA2Na (ethylenediamine-tetraacetic acid disodium salt) (30 g/L), 37% formaldehyde (3 ml/L), a small amount of stabilizer (such as bipyridine), and polyethylene glycol with aqueous sodium hydroxide to pH 12.2 for 45 to 150 minutes, and then cleaned with water. (10) As a soft etching process, the target structure is dipped in a 25° C. solution mixture of sodium persuifate (150 g/L) and concentrated sulfuric acid (10 ml/L) for 2 minutes, and then cleaned with water. (11) As an activation process, the target structure is dipped in concentrated sulfuric acid (100 ml/L) at a room temperature for 2 minutes, and then cleaned with water. (12) As a catalyzation process, the target structure is dipped in a 25° C. solution mixture of palladium chloride (170 mg/L), concentrated hydrochloric acid (1 ml/L), and an additive (such as copper salt) for 5 minutes, and then cleaned with water. (13) For alkaline electroless Ni plating, the target structure is dipped in a 90° C. solution mixture (adjusted to the pH range of 8 to 9 with aqueous sodium hydroxide) of nickel sulfate (26 g/L), sodium citrate (60 g/L), sodium hypophosphite (21 g/L), and boric acid (30 g/L) for 5 to 18 minutes, cleaned with water, and then further dried at 150° C. for 60 minutes.

In cleaning with water in each of the steps, cleaning with running water is performed for 2 minutes, and cleaning with running pure water is performed for 2 minutes. By the film depositing step, the shield layer SL including the laminated film of a Cu plating film and an Ni plating film is formed. Thereafter, heating at 150° C. is performed for 1 hour. In the heating step, holes through which hydrogen leaks out, which are observed in the Ni plating film immediately after the formation of the shield layer SL, are closed, and minute crystal grains are coupled to each other to be coarsened. As a result, the Ni plating film having a smooth surface is formed and, further, microchannel cracks which are structures each having air permeability are formed. The Cu plating film has an electromagnetic shielding function, and the Ni plating film has an anticorrosive function. The Ni plating film also improves in corrosion resistance through a change in the crystal structure of the surface due to thermal treatment. A proper range of the thickness of the Cu plating film is considered to be, e.g., from 2 to 10 μm (It will be understood that the thickness of the Cu plating film is not limited to the range depending on other conditions). As a range of the thickness of the Cu plating film which is appropriate for mass production, a range around center values of 2.5 to 4 μm is considered to be most preferred. A proper range of the thickness of the Ni plating film is considered to be, e.g., from 0.1 to 0.3 μm (It will be understood that the thickness of the Ni plating film is not limited to the range depending on other conditions). As a range of the thickness of the Ni plating film which is appropriate for mass production, a range around a center value of 0.25 μm is considered to be most preferred. As shown in FIGS. 6 and 7 described above, the microchannel cracks are formed randomly along grain boundaries in the shield layer SL, and a proper range of the widths of the microchannel cracks in the surface of the Ni plating film is considered to be, e.g., not more than 100 nm (It will be understood that the widths of the microchannel cracks in the surface of the Ni plating film are not limited to the range depending on other conditions). A range of the widths of the microchannel cracks in the surface of the Ni plating film which is appropriate for mass production is considered to be from 1 to 60 nm, and a range around center values of 1 to 30 nm is considered to be most preferred. When heating is performed up to 260° C. in consideration of the reflow step, the widths of the microchannel cracks increase, but are not more than 100 nm. The widths of the cracks in the Cu plating film are smaller than those in the surface of the Ni plating film.

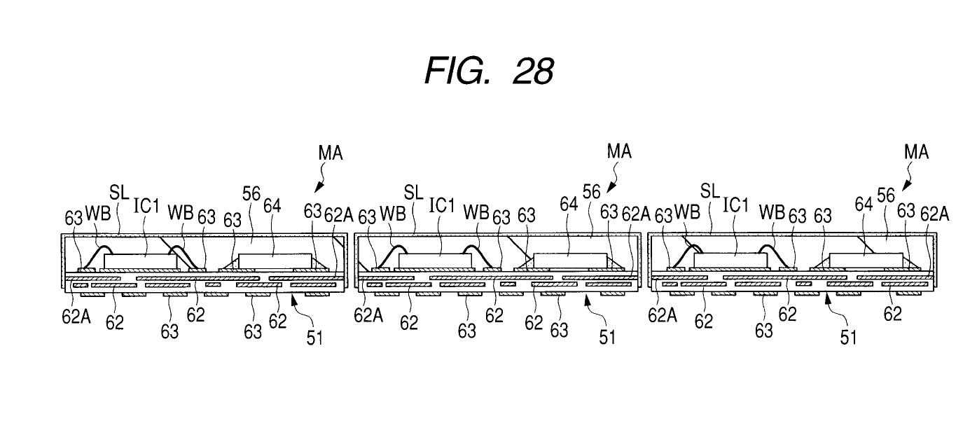

Next, as shown in FIG. 28, by further cutting the first wiring substrate 51A located below the portions of the incisions 69, the first wiring substrate 51A is divided into the individual modules MA (full-cut step P6 of FIG. 20). Thereafter, the electrical characteristics of the modules MA are measured for each of items according to product specifications so that the modules MA are screened.

Next, the step of secondary mounting the modules MA will be described.

As shown in FIG. 16 described above, the electrodes 53G and 53S for solder coupling are formed at the back surface of the module substrate 51 to allow the modules MA to be mounted over the mother board 66. Subsequently, after the modules MA are disposed over the mother board 66, reflow heating is performed at a temperature of, e.g., not less than 250° C. so that the modules MA are mounted over the mother board 66 via the solders 68. Thereafter, an electrical characteristic test is performed, whereby mounting is completed.

In the present embodiment, the description has been given to the case where the surface mounted components mounted over the module substrate 51 are covered with the high-elasticity resin 56, but the resin 56 is not limited thereto. For example, it is also possible to use a low-elasticity resin such as, e.g., a silicone resin.

The present embodiment has also described the case where the present invention is applied to a dual band method capable of handling elective waves in the two frequency bands of GSM 900 and SM 1800, but the present invention is not limited thereto. The present invention may be also applied to a triple band method capable of handling electric waves in three frequency bands of, e.g., GSM 900, GSM 1800, and GSM 1900. The present invention is also adaptable to electric waves in a 800 MHz band and in a 850 MHz band.

Thus, according to the present embodiment, even when the module MA includes the semiconductor chip IC1 formed with a surface mounted component which generates an electromagnetic wave, e.g., the power amplifier PM in a system of, e.g., a digital mobile phone, by forming the shield layer SL including the Cu/Ni laminated film over the surfaces (upper and side surfaces) of the resin 56 covering the surface mounted component by an electroless plating method, and electrically coupling the shield layer SL to the ground wiring to provide a sufficient electromagnetic shielding effect, it is possible to block the electromagnetic wave generated from the power amplifier PM with the shield layer SL.

In the shield layer SL including the Cu/Ni laminated film formed by the electroless plating method, the microchannel cracks having widths of not more than 100 nm (typically ranging from 1 to 60 nm) are formed along the grain boundaries to extend from the surface of the shield layer SL to the resin 56. Accordingly, even when moisture contained in the resin 56, moisture contained in the module substrate 51, moisture that has entered the interface between the module substrate 51 and the resin 56, or the like is evaporated by reflow heating or the like, the resulting vapor can be emitted through the microchannel cracks described above to the outside of the module MA. As a result, even when moisture is evaporated by reflow heating or the like, volume expansion does not occur, and the peeling of the shield layer SL can be prevented.

In addition, by forming the shield film SL including the Cu/Ni laminated film by the electroless plating method, the shield layer SL having an excellent spreading property can be obtained. As a result, even when the linear expansion coefficient of the shield layer SL and the linear expansion coefficients of the other component materials are different from each other, and deformation occurs during the reflow heating or actual operation of the module MA, it is possible to inhibit the occurrence of the fracture, cracking, and the like of the shield layer SL resulting from stress concentration. Due to the foregoing, it is possible to provide the module MA having an electromagnetic shielding effect and high reliability against reflow heating.

Moreover, in the present embodiment, the shield layer SL is formed only over the module MA including the surface mounted component which generates an electromagnetic wave and, unlike in the case where a metal cap is used, it is unnecessary to cover all the components mounted over the main surface of the mother board 66. Accordingly, the plan view area of the semiconductor device can be reduced to a value smaller than in the case where the metal cap is used, and the height thereof can also be reduced. Therefore, it is possible to achieve a reduction in the size of the semiconductor device.

Further, in the present embodiment, by forming the shield layer SL including the Cu/Ni laminated film by the electroless plating method, the shield layer SL having excellent followability can be obtained. Accordingly, even when the shield layer SL is formed over the surfaces (upper and side surfaces) of the resin 56, a laser marked character inscribed in the resin 56 can be recognized, and therefore a versatile laser marker can be used. As a result, it is possible to inhibit an increase in the manufacturing cost of the semiconductor device.

In the present embodiment, by forming the shield layer SL including the Cu/Ni multilayer film by the electroless plating method, even when the size and shape of the module MA is changed, the shield layer SL of a uniform material and a uniform thickness can be formed. This allows the formation of the shield layer SL having an electromagnetic shielding effect with respect to the various modules MA without significantly altering a film deposition device, film deposition conditions, and the like for the shield layer SL. Therefore, it is possible to inhibit an increase in the manufacturing cost of the semiconductor device.

While the invention achieved by the present inventors has been specifically described heretofore based on the embodiments thereof, the present invention is not limited thereto. It will be easily appreciated that various modification and changes can be made in the invention without departing from the gist thereof.

What is claimed is:

1. A semiconductor device comprising:
a module substrate;
a plurality of components mounted over a component mounting surface of the module substrate;
a resin formed so as to cover the plurality of components; and
a shield layer including a metal film formed over a surface of the resin,
wherein a plurality of microchannel cracks are formed in the shield layer.

2. A semiconductor device according to claim 1,
wherein the microchannel cracks in the shield layer are formed randomly along a grain boundary and in a net-like configuration without being connected to each other in a straight line, and form a plurality of paths extending from the surface of the resin to a surface of the shield layer.

3. A semiconductor device according to claim 1,
wherein a width of each of the microchannel cracks ranges from 1 to 60 nm.

4. A semiconductor device according to claim 1,
wherein the shield layer includes a laminated film of a first film which is formed by an electroless plating method and has an electromagnetic shielding function, and a second film which is formed over the first film by an electroless plating method and has an anticorrosive function.

5. A semiconductor device according to claim 1,
wherein the shield layer includes a laminated film of a copper film formed by an electroless plating method and a nickel film formed over the copper film by an electroless plating method.

6. A semiconductor device according to claim 5,
wherein a thickness of the copper film ranges from 2 to 10 μM.

7. A semiconductor device according to claim 6,
wherein a thickness of the nickel film ranges from 0.1 to 0.3 μm.

8. A semiconductor device according to claim 1,
wherein the shield layer includes a laminated film of a copper film formed by an electroless plating method and a tin film, a zinc film, a bismuth film, or a gold film formed over the copper film by an electroless plating method.

9. A semiconductor device according to claim 1,
wherein a part of inner-layer wiring of the module substrate is led out to a side surface of the module substrate, and the part of the inner-layer wiring led out to the side surface of the module substrate is electrically coupled to the shield layer at the side surface of the module substrate.

10. A semiconductor device according to claim 1,
wherein a part of inner-layer wiring electrically coupled to the shield layer is ground wiring.

11. A semiconductor device according to claim 1,
wherein a wiring layer of a part of inner-layer wiring is used for ground wiring, and a major part of the wiring layer of the part of the inner-layer wiring is the ground wiring.

12. A semiconductor device according to claim 1, further comprising:
a plurality of electrodes provided at a back surface of the module substrate,
wherein the module substrate is mounted over a main surface of a mother board via the electrodes.

13. A semiconductor device including an RF power amplification circuit, the semiconductor device comprising:
a module substrate;
a semiconductor chip including a transistor mounted over a main surface of the module substrate, and forming the RF power amplification circuit;
chip components mounted over the main surface of the module substrate, and including a passive element;
a resin formed so as to cover the main surface of the module substrate, the semiconductor chip, and the chip components; and
a shield layer including a metal film formed over a surface of the resin,
wherein a plurality of microchannel cracks are formed in the shield layer.

14. A semiconductor device according to claim 13,
wherein the shield layer includes a laminated film of a copper film and a nickel film formed over the copper film.

15. A semiconductor device according to claim 14,
wherein the copper film and the nickel film are each formed by an electroless plating method.

16. A semiconductor device according to claim 13,
wherein a width of each of the microchannel cracks ranges from 1 to 60 nm.

17. A semiconductor device according to claim 13,
wherein the semiconductor device is mounted in mobile communication equipment.

18. A manufacturing method of a semiconductor device, comprising the steps of:
(a) preparing a sheet-like first wiring substrate in which a plurality of module regions are arranged in a first direction and in a second direction orthogonal to the first direction;
(b) mounting a plurality of components over a component mounting surface of the first wiring substrate;
(c) molding the mounted components with a resin;
(d) cutting, from above the resin, a part of each of the resin and the first wiring substrate in the first direction and in the second direction to make respective incisions around the individual module regions;
(e) forming, over a surface of the resin and in the incision portions of the first wiring substrate, a shield layer including a laminated film of a first film having an electromagnetic shielding function and a second film having an anticorrosive function by an electroless plating method; and
(f) cutting the first wiring substrate located below the incision portions of the first wiring substrate to divide the first wiring substrate into individual modules.

19. A manufacturing method of a semiconductor device according to claim 18,
wherein the first film is a copper film, and the second film is a nickel film.

20. A manufacturing method of a semiconductor device according to claim 19,
wherein a thickness of the copper film ranges from 2 to 10 μm.

21. A manufacturing method of a semiconductor device according to claim 19,
wherein a thickness of the nickel film ranges from 0.1 to 0.3 μm.

22. A manufacturing method of a semiconductor device according to claim 18,
wherein the first film is a copper film, and the second film includes a laminated film of any two or more of a tin film, a zinc film, a bismuth film, and a gold film.

23. A manufacturing method of a semiconductor device according to claim 18, further comprising, after the step (f), the step of:
(g) disposing the modules over a main surface of a mother board via a solder, and then performing reflow heating.

24. A manufacturing method of a semiconductor device according to claim 23,
wherein the reflow heating is performed at a temperature of not less than 250° C.

25. A manufacturing method of a semiconductor device according to claim 18,
wherein, in the step (d), a part of the first wiring substrate is cut such that a part of inner-layer wiring of each of the module regions is exposed at a side surface of the module region, and
wherein, in the step (e), the shield layer is formed so as to be electrically coupled to the part of the inner-layer wiring exposed at the side surface of the module region.

26. A manufacturing method of a semiconductor device according to claim 25,
wherein the part of the inner-layer wiring electrically coupled to the shield layer is ground wiring.
